(19) United States
(12) Patent Application Publication
(10) Pub. No.: US 2025/0254857 A1
(43) Pub. Date: Aug. 7, 2025

(54) SEMICONDUCTOR DEVICE INCLUDING SUPPORTER PATTERN

(71) Applicant: Samsung Electronics Co., Ltd., Suwon-si (KR)

(72) Inventors: Heejae Chae, Suwon-si (KR); Yongkwan Kim, Suwon-si (KR); Huijung Kim, Suwon-si (KR); Hyunjin Lee, Suwon-si (KR); Yun Choi, Suwon-si (KR)

(21) Appl. No.: 18/903,720

(22) Filed: Oct. 1, 2024

(30) Foreign Application Priority Data
Feb. 1, 2024 (KR) 10-2024-0016064

(51) Int. Cl. H10B 12/00

(52) U.S. Cl. CPC H10B 12/315; H10B 12/50

(57) ABSTRACT

A semiconductor device includes a plurality of active regions disposed at a substrate, a device isolation layer disposed at the substrate and surrounding each of the plurality of active regions, a supporter pattern surrounded by the device isolation layer and disposed in a space between two active regions of the plurality of active regions, a cell gate structure intersecting the plurality of active regions, the cell gate structure including a gate dielectric layer, a gate electrode on the gate dielectric layer, and a gate capping layer on the gate electrode, and a bit line structure intersecting one of the plurality of active regions and the cell gate structure. A lower surface of the supporter pattern is in contact with the device isolation layer, and an upper surface of the supporter pattern is in contact with the gate electrode.

### CROSS-REFERENCE TO RELATED APPLICATION(S)

This application claims benefit of priority to Korean Patent Application No. 10-2024-0016064 filed on Feb. 1, 2024 in the Korean Intellectual Property Office, the disclosure of which is herein incorporated by reference in its entirety.

### BACKGROUND

The present inventive concept relates to a semiconductor device including a supporter pattern.

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it is desirable to implement patterns having a fine width or a fine isolation distance.

### SUMMARY

An aspect of the present inventive concept provides a semiconductor device including a supporter pattern disposed between active regions, the supporter pattern surrounded by a device isolation layer.

According to an aspect of the present disclosure, a semiconductor device includes a plurality of active regions disposed at a substrate, a device isolation layer disposed at the substrate and surrounding each of the plurality of active regions, a supporter pattern surrounded by the device isolation layer and disposed in a space between two active regions of the plurality of active regions, a cell gate structure intersecting the plurality of active regions, the cell gate structure including a gate dielectric layer, a gate electrode on the gate dielectric layer, and a gate capping layer on the gate electrode, and a bit line structure intersecting one of the plurality of active regions and the cell gate structure. A lower surface of the supporter pattern is in contact with the device isolation layer, and an upper surface of the supporter pattern is in contact with the gate electrode.

According to an aspect of the present disclosure, a semiconductor device includes a substrate having a first trench and a second trench extending from an upper surface of the substrate toward a lower surface of the substrate, wherein a lower surface of the first trench is higher than a lower surface of the second trench, a first active region disposed at the substrate and defined by the first trench and the second trench, wherein the first active region extends in a first horizontal direction, a device isolation layer including a first isolation layer filling the first trench, and a second isolation layer filling the second trench, a supporter pattern disposed on the second isolation layer, a cell gate structure intersecting the first active region, the cell gate structure extending in a second horizontal direction intersecting the first horizontal direction, and the cell gate structure including a gate dielectric layer, a gate electrode on the gate dielectric layer, and a gate capping layer on the gate electrode, and a bit line structure intersecting the first active region and the cell gate structure, the bit line structure extending in a third horizontal direction intersecting the first horizontal direction and the second horizontal direction. A lower surface of the supporter pattern is in contact with the device isolation layer, and an upper surface of the supporter pattern is in contact with the gate electrode.

According to an aspect of the present disclosure, a semiconductor device includes a plurality of active regions disposed at a substrate, a device isolation layer disposed at the substrate and surrounding each of the plurality of active regions, a supporter pattern surrounded by the device isolation layer and disposed in a space between two active regions of the plurality of active regions, a plurality of cell gate structures intersecting the plurality of active regions, each of the plurality of cell gate structures including a gate dielectric layer, a gate electrode on the gate dielectric layer, and a gate capping layer on the gate electrode, a plurality of bit line structures intersecting the plurality of active regions and the plurality of cell gate structures, a contact plug disposed on a side surface of one of the plurality of bit line structures, wherein the contact plug is electrically connected to one of the plurality of active regions, a landing pad on the contact plug, and a capacitor structure on the landing pad. A lower surface of the supporter pattern is in contact with the device isolation layer, an upper surface of the supporter pattern is in contact with the gate electrode, and a side surface of the supporter pattern is in contact with the device isolation layer and the gate dielectric layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor device according to an example embodiment;

FIG. 2 is a partially enlarged view of FIG. 1;

FIG. 3 is a vertical cross-sectional view of the semiconductor device illustrated in FIG. 2, taken along lines I-I′ and II-II′;

FIG. 4 is a vertical cross-sectional view of the semiconductor device illustrated in FIG. 2, taken along line III-III′;

FIG. 5 is a vertical cross-sectional view of the semiconductor device illustrated in FIG. 2, taken along line IV-IV′;

FIG. 6 is a partially enlarged view of FIG. 2;

FIG. 7 is a partially enlarged view of FIG. 4;

FIGS. 8 to 11 are vertical cross-sectional views of semiconductor devices according to example embodiments;

FIGS. 12A, 13A, 14A, 15A, 16A, 17A, and 21A are plan views of sequential processes of a method of manufacturing a semiconductor device according to an example embodiment, and FIGS. 12B, 13B, 14B, 15B, 16B, 17B, 18-20, and 21B are vertical cross-sectional views of sequential processes of the method of manufacturing the semiconductor device according to an example embodiment;

FIGS. 22 to 25 are vertical cross-sectional views of sequential processes of a method of manufacturing a semiconductor device according to an example embodiment;

FIGS. 26A, 26B, 27A, 27B, 28A and 28B are plan views and vertical cross-sectional views of sequential processes of a method of manufacturing a semiconductor device according to an example embodiment; and

FIGS. 29 to 31 are plan views of semiconductor devices according to example embodiments.

### DETAILED DESCRIPTION

Hereinafter, example embodiments of the present inventive concept will be described with reference to the attached drawings.

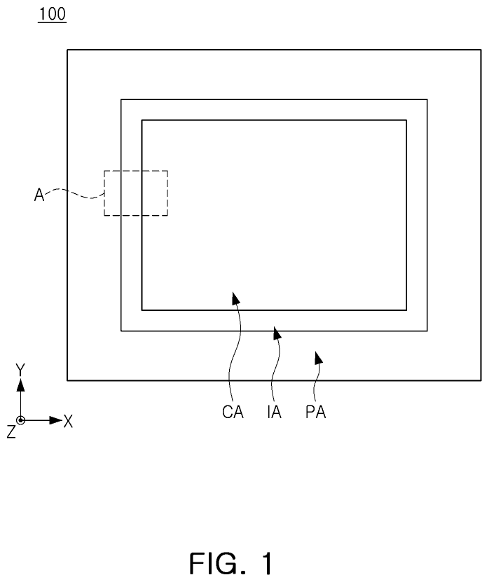

FIG. 1 is a plan view of a semiconductor device according to an example embodiment.

Referring to FIG. 1, a semiconductor device 100 according to an example embodiment of the present inventive concept may include a cell region CA, an interface region IA, and a peripheral circuit region PA. The peripheral circuit region PA may be disposed to surround the cell region CA, and the interface region IA may be disposed between the cell region CA and the peripheral circuit region PA. The semiconductor device 100 may be applied to, for example, a cell array of a dynamic random access memory (DRAM), but the present inventive concept is not limited thereto. The cell region CA may refer to a region in which a memory cell of a DRAM device is disposed, and the interface region IA may be a region between the cell region CA and the peripheral circuit region PA, the region in which a row decoder and a sense amplifier are disposed.

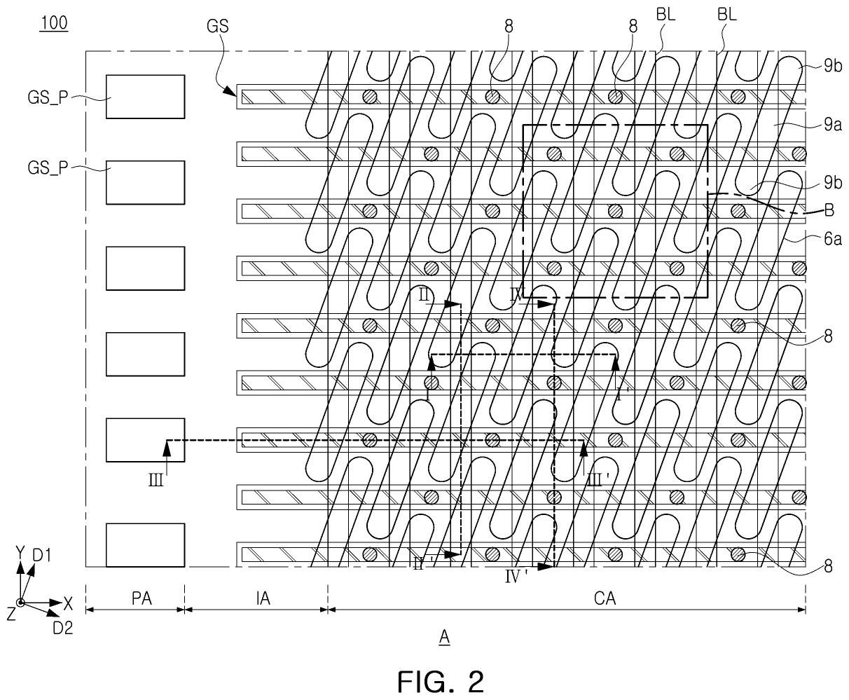

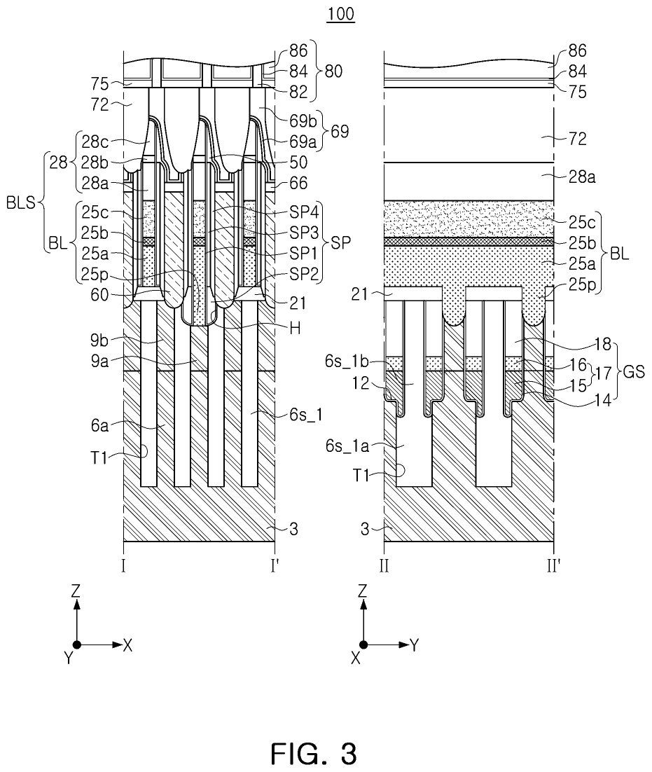

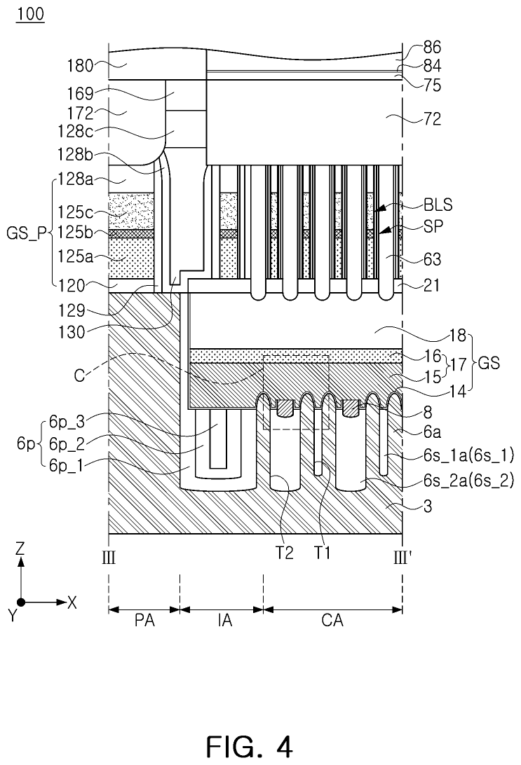

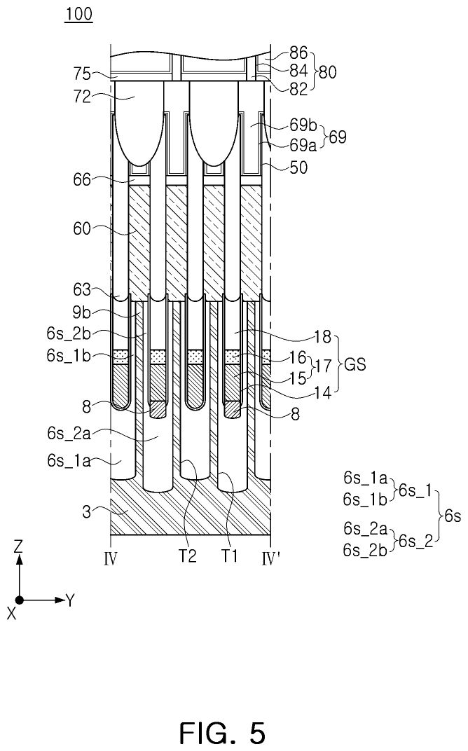

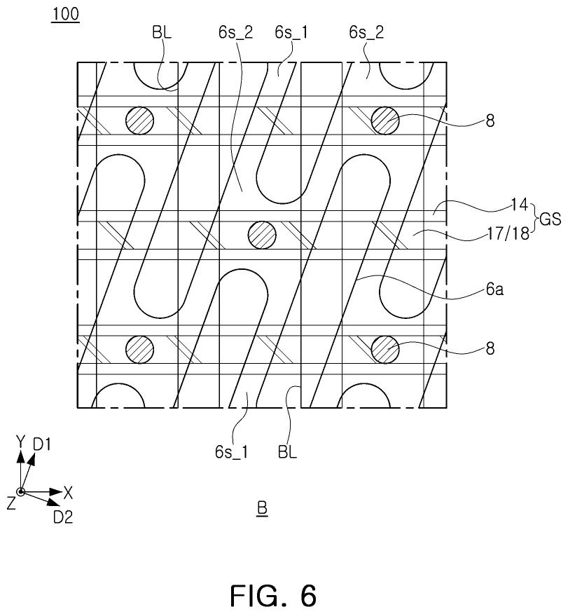

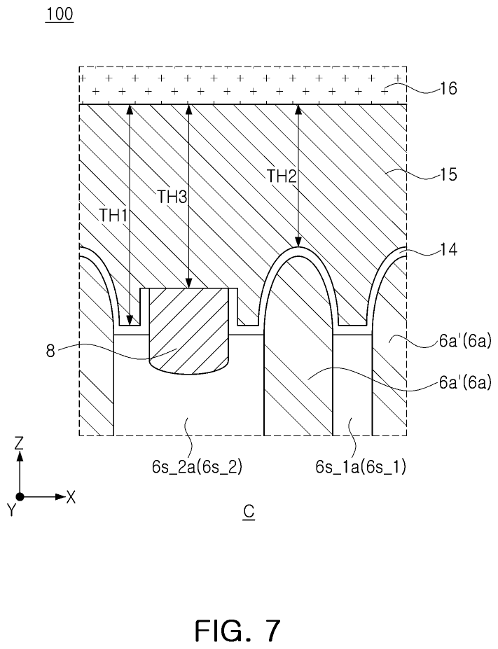

FIG. 2 is a partially enlarged view of FIG. 1. FIG. 2 may correspond to region A of FIG. 1. FIG. 3 is a vertical cross-sectional view of the semiconductor device illustrated in FIG. 2, taken along lines I-I′ and II-II′. FIG. 4 is a vertical cross-sectional view of the semiconductor device illustrated in FIG. 2, taken along line III-III′. FIG. 5 is a vertical cross-sectional view of the semiconductor device illustrated in FIG. 2, taken along line IV-IV′. FIG. 6 is a partially enlarged view of FIG. 2. FIG. 6 may correspond to region B of FIG. 2. FIG. 7 is a partially enlarged view of FIG. 4. FIG. 7 may correspond to region C of FIG. 4.

Referring to FIGS. 2 to 7, a substrate 3 of the semiconductor device 100 according to an example embodiment of the present inventive concept may include a cell region CA, an interface region IA, and a peripheral circuit region PA. In the cell region CA, the semiconductor device 100 may include an active region 6a, a device isolation layer 6s, a supporter pattern 8, a cell gate structure GS, a buffer layer 21, a bit line structure BLS, a spacer structure SP, a contact plug 60, a landing pad 69, and a capacitor structure 80.

The substrate 3 may include or may be formed of a semiconductor material, for example, a group IV semiconductor, a group III-V compound semiconductor, or a group II-VI compound semiconductor. For example, the group IV semiconductor may include silicon, germanium, or silicon-germanium. The substrate 3 may include or may be a silicon substrate, a silicon on insulator (SOI) substrate, a germanium substrate, a germanium on insulator (GOI) substrate, a silicon-germanium substrate, or a substrate including an epitaxial layer.

The device isolation layer 6s may be an insulating layer downwardly extending from an upper surface of the substrate 3 toward a lower surface of the substrate 3, and may define the active region 6a. For example, the active region 6a may correspond to a portion of the upper surface of the substrate 3 surrounded by the device isolation layer 6s. When viewed in a plan view, the active region 6a may have a bar shape having a minor axis and a major axis, and may extend in a direction, inclined to an X-direction and a Y-direction (i.e., in a direction between the X-direction and the Y-direction). A major axis direction of the active region 6a may be referred to as a first horizontal direction D1, and a minor axis direction may be referred to as a second horizontal direction D2. The active region 6a may extend in the first horizontal direction D1.

The active region 6a may be defined by a first trench T1 and a second trench T2 formed at the upper surface of the substrate 3. For example, the first trench T1 and the second trench T2 may be formed by etching the substrate 3, and the active region 6a may correspond to a portion of the upper surface of the substrate 3 in which the first trench T1 and the second trench T2 are not formed. In an example embodiment, the second trench T2 may be formed to be deeper than the first trench T1. For example, a lower surface of the second trench T2 may be positioned at a level lower than that of a lower surface of the first trench T1. In an example embodiment, a horizontal width of the second trench T2 in the X-direction may be greater than a horizontal width of the first trench T1 in the X-direction. The first trench T1 may extend in the first horizontal direction D1 between the active regions 6a. The second trench T2 may be disposed between active regions 6a adjacent to each other in the first horizontal direction D1. In an embodiment, the first trench T1 and the second trench T2 may be connected with each other, thereby defining each of the active regions 6a.

The active region 6a may include first and second impurity regions 9a and 9b extending from the upper surface of the substrate 3 to have a predetermined depth. The first and second impurity regions 9a and 9b may be spaced apart from each other. The first and second impurity regions 9a and 9b may serve as source/drain regions of a transistor. For example, with respect to one active region 6a, two cell gate structures GS may cross the one active region 6a, a drain region may be formed between the two cell gate structures GS, and source regions may be formed in regions opposite to the drain region with respect to the two cell gate structures GS. For example, the first impurity region 9a may correspond to the drain region, and the second impurity region 9b may correspond to the source region. The source region and the drain region, formed by the first and second impurity regions 9a and 9b caused by doping or ion implantation of the same impurities, may be interchangeably referred to depending on a circuit configuration of transistors. The first and second impurity regions 9a and 9b may include impurities having a conductivity type opposite to that of the substrate 3. For example, the active regions 6a may include P-type impurities, and the first and second impurity regions 9a and 9b may include N-type impurities.

The device isolation layer 6s may include a first isolation layer 6s_1 filling the first trench T1, and a second isolation layer 6s_2 filling the second trench T2. The first isolation layer 6s_1 may extend in the first horizontal direction D1 between the active regions 6a. In an example embodiment, a horizontal width of the second isolation layer 6s_2 in the X-direction may be greater than a horizontal width of the first isolation layer 6s_1 in the X-direction. The second isolation layer 6s_2 may be disposed between active regions 6a adjacent to each other in the first horizontal direction D1. When viewed in a plan view, the first isolation layer 6s_1 may be disposed between two adjacent active regions 6a, and the second isolation layer 6s_2 may be disposed between four adjacent active regions 6a.

The first isolation layer 6s_1 may include a lower portion 6s_la and an upper portion 6s_1b, and the second isolation layer 6s_2 may include a lower portion 6s_2a and an upper portion 6s_2b. For example, a portion of the first isolation layer 6s_1, positioned at a level lower than that of the cell gate structure GS, may be referred to as a lower portion 6s_la, and a portion of the second isolation layer 6s_2, positioned at a level lower than that of the cell gate structure GS, may be referred to as a lower portion 6s_2a. The lower portion 6s_la of the first isolation layer 6s_1 and the lower portion 6s_2a of the second isolation layer 6s_2 may be in contact with a lower surface of the cell gate structure GS. In an embodiment, the entirety of an upper surface of the lower portion 6s_la may contact a portion of a lower surface of the cell gate structure GS, and an upper surface of the lower portion 6s_2a may contact a side surface and a lower surface of the supporter pattern 8 in addition to a portion of the lower surface of the cell gate structure GS. The upper portion 6s_1b of the first isolation layer 6s_1 and the upper portion 6s_2b of the second isolation layer 6s_2 may be in contact with the side surface of the cell gate structure GS.

An upper surface of the lower portion 6s_2a of the second isolation layer 6s_2 may be disposed at a level the same as that of an upper surface of the lower portion 6s_la of the first isolation layer 6s_1. A lower surface of the lower portion 6s_2a of the second isolation layer 6s_2 may be disposed at a level lower than that of a lower surface of the lower portion 6s_la of the first isolation layer 6s_1. An upper surface of the upper portion 6s_2b of the second isolation layer 6s_2 may be coplanar with an upper surface of the upper portion 6s_la of the first isolation layer 6s_1 and the upper surface of the substrate 3.

The first isolation layer 6s_1 may be physically continuous with the second isolation layer 6s_2. For example, the first isolation layer 6s_1 may include a material which is the same as that of the second isolation layer 6s_2. The first isolation layer 6s_1 and the second isolation layer 6s_2 may include or may be formed of silicon oxide, silicon nitride, silicon oxynitride, or a combination thereof. In an example embodiment, the first isolation layer 6s_1 and the second isolation layer 6s_2 may include or may be formed of silicon oxide.

The supporter pattern 8 may be disposed between the active regions 6a, and may be surrounded by the device isolation layer 6s. For example, the supporter pattern 8 may be disposed between active regions 6a adjacent to each other in the first horizontal direction D1. The supporter pattern 8 may be disposed on the lower portion 6s_2a of the second isolation layer 6s_2, and a portion of the supporter pattern 8 may be buried in the lower portion 6s_2a of the second isolation layer 6s_2. For example, an upper surface of the supporter pattern 8 may be disposed at a level higher than those of upper surfaces of the lower portion 6s_la of the first isolation layer 6s_1 and the lower portion 6s_2a of the second isolation layer 6s_2, and a lower surface of the supporter pattern 8 may be disposed at a level lower than those of the upper surfaces of the lower portion 6s_la of the first isolation layer 6s_1 and the lower portion 6s_2a of the second isolation layer 6s_2. The upper surface of the supporter pattern 8 may be disposed at a level the same as or lower than that of an upper end of a portion 6a′ of the active region 6a vertically overlapping the cell gate structure GS. For example, the portion 6a′ of the active region 6a may have an upper end positioned at a first vertical level, and the upper surface of the supporter pattern 8 may be positioned at a second vertical level which is the same as or lower than the first vertical level. In an embodiment, the lower surface of the supporter pattern 8 may contact the device isolation layer 6s, and an upper surface of the supporter pattern 8 may contact a gate electrode 17, which will be described later. A horizontal width of the supporter pattern 8 in the X-direction may be less than a horizontal width of the second isolation layer 6s_2 in the X-direction.

The supporter pattern 8 may include or may be formed of a material having etch selectivity with respect to the first isolation layer 6s_1 and the second isolation layer 6s_2. In an example embodiment, the supporter pattern 8 may include or may be formed of at least one of carbon (C)-doped polysilicon, silicon germanium (SiGe), and silicon nitride (SiN). In some example embodiments, the supporter pattern 8 may include or may be formed of a conductive material such as metal or metal nitride. For example, the supporter pattern 8 may include or may be formed of at least one of titanium (Ti), titanium nitride (TiN), tantalum (Ta), tantalum nitride (TaN), tungsten (W), tungsten nitride (WN), molybdenum (Mo), and aluminum (Al).

In a cross-sectional view, the cell gate structures GS may be buried in the substrate 3. For example, the cell gate structures GS may be disposed in the inside of the gate trench 12 formed in the substrate 3. The cell gate structure GS may include a gate dielectric layer 14, a gate electrode 17, and a gate capping layer 18, which are disposed in the inside of the gate trench 12. The gate dielectric layer 14 may be conformally formed on an inner wall of the gate trench 12. The gate electrode 17 may be disposed on a lower portion of the gate trench 12, and the gate capping layer 18 may be disposed on an upper portion of the cell gate structure GS and fill the gate trench 12.

The gate dielectric layer 14 may include or may be formed of silicon oxide or an insulating material having a high dielectric constant. In example embodiments, the gate dielectric layer 14 may be a layer formed by oxidizing the first active region 6a, or may be a layer formed using deposition. The gate electrode 17 may include a first electrode layer 15, and a second electrode layer 16 on the first electrode layer 15. In an example embodiment, the first electrode layer 15 may not have a constant vertical thickness. For example, a first portion of the first electrode layer 15, vertically overlapping the device isolation layer 6s, may have a first thickness TH1, a minimum thickness of a second portion of the first electrode layer 15, vertically overlapping the active region 6a, may be a second thickness TH2, and a third portion of the first electrode layer 15, overlapping the supporter pattern 8, may have a third thickness TH3. The third thickness TH3 may be greater than the second thickness TH2, and may be less than the first thickness TH1.

The first electrode layer 15 may include or may be formed of at least one of titanium (Ti), titanium nitride (TiN), tantalum (Ta), tantalum nitride (TaN), tungsten (W), tungsten nitride (WN), and aluminum (Al). In an example embodiment, the first electrode layer 15 may include or may be formed of titanium nitride (TiN). The second electrode layer 15 may include or may be formed of polysilicon. The gate capping layer 18 may include or may be formed of silicon nitride.

A side surface of an upper portion of the supporter pattern 8 may be covered by the gate dielectric layer 14. The upper surface of the supporter pattern 8 may not be covered by the gate dielectric layer 14, and may be in contact with the first electrode layer 15 of the gate electrode 17. In an embodiment, an upper end of a portion of the gate dielectric layer 14, covering a side surface of the supporter pattern 8, is disposed at a level, which is the same as that of the upper surface of the supporter pattern 8, but the present inventive concept is not limited thereto.

When viewed in a plan view, the supporter pattern 8 may overlap the cell gate structure GS. For example, the supporter pattern 8 may vertically overlap the gate electrode 17 of the cell gate structure GS. In an embodiment, a horizontal width of the supporter pattern 8 in the Y-direction is equal to a horizontal width of the gate electrode 17 in the Y-direction, but the present inventive concept is not limited thereto. In some example embodiments, the horizontal width of the supporter pattern 8 in the Y-direction may be greater or less than the horizontal width of the gate electrode 17 in the Y-direction. When viewed in a plan view, the supporter pattern 8 may have a circular shape. In some example embodiments, when viewed in a plan view, the supporter pattern 8 may have various shapes, such as a rectangular shape, an oval shape, or the like.

The supporter patterns 8 may be spaced apart from each other in the X-direction and the Y-direction. The supporter patterns 8 may be below each cell gate structure GS and may be spaced apart from each other in the X-direction. In an example embodiment, when viewed in a plan view, the supporter patterns 8 may be disposed to be adjacent to ends of each active region 6a in the first horizontal direction D1. For example, one active region 6a may be disposed between supporter patterns 8 adjacent to each other in the first horizontal direction D1. However, the arrangement of the supporter patterns 8 is exemplary, and is not limited thereto.

The buffer layer 21 may be disposed on the active region 6a, the device isolation layer 6s, and the cell gate structure GS. The buffer layer 21 may include or may be formed of silicon oxide, silicon nitride, silicon oxynitride, or a combination thereof. The buffer layer 21 may be a single layer or multiple layers.

The bit line structures BLS may extend in the Y-direction, and may be spaced apart from each other in the X-direction. The bit line structure BLS may have a bar shape extending in the Y-direction. The bit line structure BLS may include a bit line BL and a bit line capping layer 28 on the bit line BL. The bit line BL may include a first conductive layer 25a, a second conductive layer 25b, and a third conductive layer 25c, which are sequentially stacked on the buffer layer 21. The first conductive layer 25a may include or may be formed of polysilicon. The second conductive layer 25b may include or may be formed of a metal-semiconductor compound. For example, the metal-semiconductor compound may be a layer obtained by silicidizing a portion of the first conductive layer 25a. For example, the metal-semiconductor compound may include or may be formed of cobalt silicide (CoSi), titanium silicide (TiSi), nickel silicide (NiSi), tungsten silicide (WSi), or other metal silicides, or may include or may be formed of nitride such as TiSiN. The third conductive layer 25c may include or may be formed of a metal material such as titanium (Ti), tantalum (Ta), tungsten (W), and aluminum (Al). The bit line BL may further include a plug portion 25p below the first conductive layer 25a. The plug portion 25p may extend downwardly and may be in contact with the first impurity region 9a. The plug portion 25p may be positioned in a contact hole H, formed at the upper surface of the substrate 3. The plug portion 25p may be in contact with the first impurity region 9a, a central portion of the active region 6a. When viewed in a plan view, the plug portion 25p may overlap the first impurity region 9a. The plug portion 25p may electrically connect the active region 6a to the bit line structure BLS. The plug portion 25p may include or may be formed of a material, the same as that of the first conductive layer 25a.

The bit line capping layer 28 may include a first capping layer 28a, a second capping layer 28b, and a third capping layer 28c, which are disposed on the bit line BL. A side surface of the first capping layer 28a may be coplanar with the first conductive layer 25a, the second conductive layer 25b, and the third conductive layer 25c. The first capping layer 28a, the second capping layer 28b, and the third capping layer 28c may include or may be formed of silicon oxide, silicon nitride, silicon oxynitride, or a combination thereof, for example, silicon nitride.

The spacer structures SP may be disposed on opposite side surfaces of the bit line structures BLS, respectively, and may extend in the Y-direction along the side surface of the bit line structures BLS. The spacer structure SP may include a first spacer SP1, a second spacer SP2, a third spacer SP3, and a fourth spacer SP4 disposed on the side surface of the bit line structures BLS. The first spacer SP1 may be conformally disposed along side surfaces of the bit line structure BLS and the contact hole H. The second spacer SP2 may be disposed on the first spacer SP1, and may fill the contact hole H. The third spacer SP3 may cover a side surface of the first spacer SP1, and the fourth spacer SP4 may cover a side surface of the third spacer SP3. The third spacer SP3 and the fourth spacer SP4 may cover an upper surface of the second spacer SP2. In an embodiment, a lower end of each of the third spacer SP3 and the fourth spacer SP4 may contact the upper surface of the second spacer SP2. The first spacer SP1, the second spacer SP2, the third spacer SP3, and the fourth spacer SP4 may include or may be formed of silicon oxide, silicon nitride, silicon oxynitride, or a combination thereof. The spacer structure SP according to the present inventive concept is exemplary, and the material and number of layers of the spacer structure SP are not limited thereto, and may be changed in various manners.

The contact plug 60 may be disposed between the bit line structures BLS, and may be in contact with the spacer structures SP. The contact plugs 60 may be disposed between the bit line structures BLS and the cell gate structures GS.

A lower end of the contact plug 60 may be positioned at a level lower than that of the upper surface of the substrate 3, and an upper surface of the contact plug 60 may be positioned at a level lower than that of an upper end of the bit line structure BLS. The contact plug 60 may extend into the substrate 3 to be in contact with the second impurity region 9b of the active region 6a, and may be electrically connected to the second impurity region 9b. The contact plug 60 may include or may be formed of a conductive material, for example, at least one of polysilicon (Si), titanium (Ti), titanium nitride (TiN), tantalum (Ta), tantalum nitride (TaN), tungsten (W), tungsten nitride (WN), and aluminum (Al). In an example embodiment, the contact plug 60 may include or may be formed of doped polysilicon doped with N-type impurities such as phosphorus (P), arsenic (As), and antimony (Sb).

The fence structure 63 may be disposed between the bit line structures BLS, and may vertically overlap the cell gate structure GS. The fence structures 63 may be disposed alternately with the contact plugs 60 in the Y-direction. The fence structures 63 may spatially isolate the contact plugs 60 from each other, and electrically insulate the contact plugs 60 from each other. A lower surface of the fence structure 63 may be in contact with the gate capping layer 18 of the cell gate structure GS. In an example embodiment, a lower end of the fence structure 63 may be positioned at a level lower than that of the upper surface of the substrate 3. The fence structure 63 may include or may be formed of an insulating material, for example, silicon nitride.

The semiconductor device 100 may further include a metal-semiconductor compound layer 66, disposed on the upper surface of the contact plug 60. The metal-semiconductor compound layer 66 may be in contact with a side surface of the spacer structure SP and a side surface of the fence structure 63.

The landing pad 69 may be disposed on the metal-semiconductor compound layer 66, and may include a first barrier layer 69a covering the bit line structure BLS, the spacer structure SP, and the fence structure 63, and a metal layer 69b on the first barrier layer 69a. The landing pad 69 may be electrically connected to the second impurity region 9b of the active region 6a through the contact plug 60. The metal-semiconductor compound layer 66 may include or may be formed of cobalt silicide (CoSi), titanium silicide (TiSi), nickel silicide (NiSi), tungsten silicide (WSi), or other metal silicides. In an embodiment, the metal-semiconductor compound layer 66 may include or may be formed of metal silicide of the metal included in the contact plug 60. The first barrier layer 69a may include or may be formed of metal nitride, for example, at least one of titanium nitride (TiN), tantalum nitride (TaN), and tungsten nitride (WN). The metal layer 69b may include or may be formed of a conductive material, for example, at least one of titanium (Ti), tantalum (Ta), tungsten (W), and aluminum (Al).

The semiconductor device 100 may further include an upper insulating spacer 50, covering upper portions of the bit line structure BLS, the spacer structure SP, and the fence structure 63. The upper insulating spacer 50 may be disposed between the bit line structure BLS and the first barrier layer 69a, between the spacer structure SP and the first barrier layer 69a, and between the fence structure 63 and the first barrier layer 69a.

The semiconductor device 100 may further include an insulating pattern 72 disposed between the landing pads 69. An upper surface of the insulating pattern 72 may be coplanar with an upper surface of the landing pad 69, and the insulating pattern 72 may downwardly extend to be in contact with a portion of the bit line structures BLS. The insulating pattern 72 may spatially isolate the landing pads 69 from each other, and electrically insulate the landing pads 69 from each other.

The semiconductor device 100 may further include an etch stop layer 75, covering upper surfaces of the landing pad 69 and the insulating pattern 72. The capacitor structure 80 may be disposed on the landing pad 69 and the insulating pattern 72. The capacitor structure 80 may include a lower electrode 82, a capacitor dielectric layer 84, and an upper electrode 86. The lower electrode 82 may pass through the etch stop layer 75 to be in contact with the upper surface of the landing pad 69. The capacitor dielectric layer 84 may cover the lower electrode 82 and the etch stop layer 75, and the upper electrode 86 may cover the capacitor dielectric layer 84. The capacitor structure 80 may be electrically connected to the landing pad 69 and the contact plug 60. The lower electrode 82 and the upper electrode 86 may include or may be formed of at least one of a doped semiconductor, metal nitride, metal, and metal oxide. The lower electrode 82 and the upper electrode 86 may include or may be formed of, for example, at least one of polycrystalline silicon, titanium nitride (TiN), tungsten (W), titanium (Ti), ruthenium (Ru), and tungsten nitride (WN). For example, the capacitor dielectric layer 84 may include or may be formed of at least one of high-K dielectric materials such as zirconium oxide (ZrO₂), aluminum oxide (Al₂O₃), and hafnium oxide (Hf₂O₃).

In the interface region IA, the semiconductor device 100 may further include a region isolation layer 6p. The region isolation layer 6p may be an insulating layer downwardly extending from the upper surface of the substrate 3. The region isolation layer 6p may include a first insulating layer 6p_1, a second insulating layer 6p_2, and a third insulating layer 6p_3, which are sequentially stacked or layered. The first insulating layer 6p_1 and the third insulating layer 6p_3 may include or may be formed of silicon oxide, and the second insulating layer 6p_2 may include or may be formed of silicon nitride.

In the peripheral circuit region PA, the semiconductor device 100 may further include a peripheral gate structure GS_P disposed on the substrate 3. The peripheral gate structure GS_P may include a peripheral gate dielectric layer 120, a first conductive layer 125a, a second conductive layer 125b, a third conductive layer 125c, and a peripheral gate capping layer 128a, which are sequentially stacked. The peripheral gate dielectric layer 120 may include or may be formed of silicon oxide, silicon nitride, or a high-k dielectric material. The high-K dielectric material may refer to a dielectric material having a dielectric constant, higher than that of silicon oxide. The first conductive layer 125a, the second conductive layer 125b, and the third conductive layer 125c of the peripheral gate structure GS_P may include or may be formed of materials, the same as those of the first conductive layer 25a, the second conductive layer 25b, and the third conductive layer 25c of the bit line BL, respectively. The peripheral gate capping layer 128a may include or may be formed of a material, the same as that of the first capping layer 28a of the bit line capping layer 28. However, the materials and structures of the first conductive layer 125a, the second conductive layer 125b, the third conductive layer 125c, and the peripheral gate capping layer 128a are exemplary, and are not limited thereto.

Although not illustrated, in the peripheral circuit region PA, the substrate 3 may further include impurity regions disposed to be adjacent to the peripheral gate structure GS_P.

In the peripheral circuit region PA, the semiconductor device 100 may further include a peripheral gate spacer 129, a first peripheral capping layer 128b, a second peripheral capping layer 128c, and a lower interlayer insulating layer 130. The peripheral gate spacer 129 may cover a side surface of the peripheral gate structure GS_P. For example, the peripheral gate spacers 129 may cover side surfaces of the first conductive layer 125a, the second conductive layer 125b, the third conductive layer 125c, and the peripheral gate capping layer 128a.

The first peripheral capping layer 128b may cover the substrate 3, the peripheral gate spacer 129, and the peripheral gate structure GS_P, and may be conformally formed. The lower interlayer insulating layer 130 may cover the first peripheral capping layer 128b. The second peripheral capping layer 128c may be disposed on the lower interlayer insulating layer 130 and the first peripheral capping layer 128b.

The first peripheral capping layer 128b and the second peripheral capping layer 128c may include or may be formed of materials, the same as those of the second capping layer 28b and the third capping layer 28c of the bit line capping layer 28, respectively, and may include or may be formed of, for example, silicon nitride. The lower interlayer insulating layer 130 may include or may be formed of silicon oxide, silicon nitride, silicon oxynitride, or a combination thereof, for example, silicon oxide.

In the peripheral circuit region PA, the semiconductor device 100 may further include a peripheral interconnection 169 disposed at a level the same as that of the landing pad 69. An upper surface of the peripheral interconnection 169 may be disposed at a level the same as that of the landing pad 69, and the peripheral interconnection 169 may include or may be formed of a material which is the same as that of the landing pad 69.

The semiconductor device 100 may further include a peripheral insulating pattern 172 and an upper interlayer insulating layer 180, which are disposed on the peripheral gate structure GS_P. The peripheral insulating pattern 172 may be disposed on the peripheral circuit region PA and the interface region IA, and may be disposed at a level the same as that of the insulating pattern 72. The peripheral insulating pattern 172 may be in contact with the peripheral gate structure GS_P, the lower interlayer insulating layer 130, the second peripheral capping layer 128c, and the peripheral interconnection 169. The upper interlayer insulating layer 180 may be disposed on the peripheral insulating pattern 172, on the peripheral circuit region PA and the interface region IA, and may be disposed at a level the same as that of the capacitor structure 80.

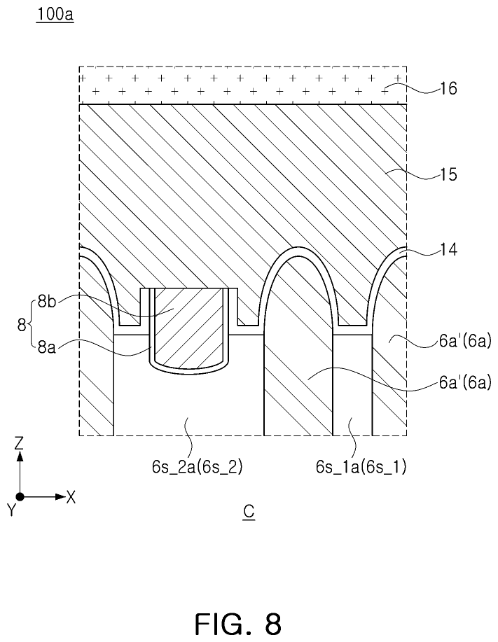

FIGS. 8 to 11 are vertical cross-sectional views of semiconductor devices according to example embodiments.

Referring to FIG. 8, a semiconductor device 100a may include a supporter pattern 8 disposed on a lower portion 6s_2a of a second isolation layer 6s_2. In an example embodiment, the supporter pattern 8 may include or may be formed of a conductive material such as metal. For example, the supporter pattern 8 may include a second barrier layer 8a, and a metal layer 8b on the second barrier layer 8a. The second barrier layer 8a may cover a lower surface and a side surface of the metal layer 8b, and may be in contact with the lower portion 6s_2a of the second isolation layer 6s_2 and a gate dielectric layer 14. For example, a portion of the second barrier layer 8a may be disposed in a space between the side surface of the metal layer 8b and the gate dielectric layer 14. In some embodiments, an upper end of the second barrier layer 8a and an upper surface of the metal layer 8b may be coplanar with each other.

The second barrier layer 8a may include or may be formed of at least one of titanium nitride (TiN), tantalum nitride (TaN), and tungsten nitride (WN). The metal layer 8b may include or may be formed of at least one of titanium (Ti), tantalum (Ta), tungsten (W), molybdenum (Mo), and aluminum (Al).

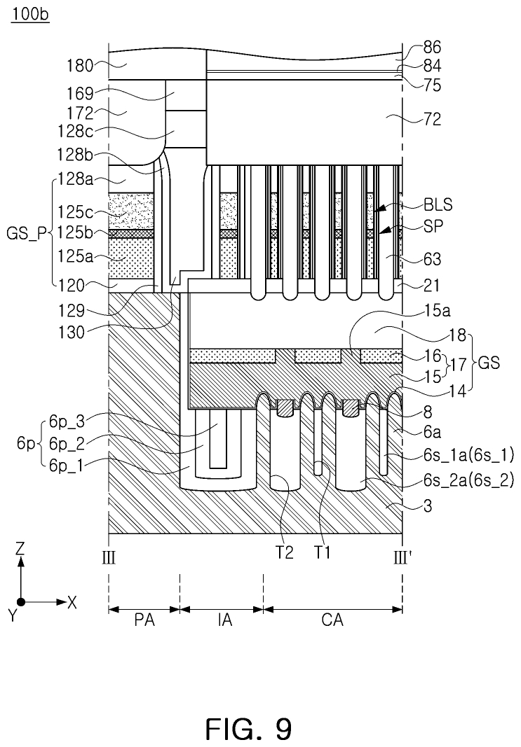

Referring to FIG. 9, a semiconductor device 100b may include a cell gate structure GS crossing an active region 6a and a device isolation layer 6s. In an example embodiment, the first electrode layer 15 of the cell gate structure GS may include a protrusion portion 15a. For example, the protrusion portion 15a may upwardly protrude from an upper surface of the first electrode layer 15, and may be in contact with a side surface of the second electrode layer 16 and a lower surface of a gate capping layer 18. An upper surface of the protrusion portion 15a may be coplanar with an upper surface of the second electrode layer 16. The protrusion portion 15a may vertically overlap a supporter pattern 8.

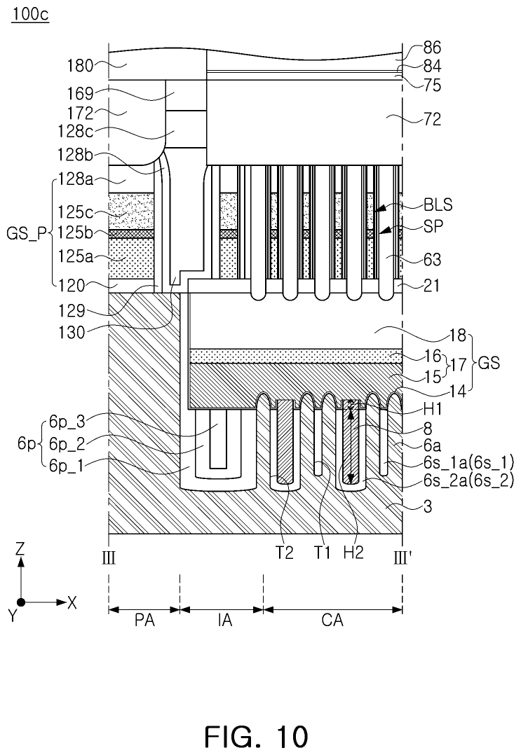

Referring to FIG. 10, a semiconductor device 100c may include a supporter pattern 8 disposed on a lower portion 6s_2a of a second isolation layer 6s_2. In an example embodiment, the supporter pattern 8 may further downwardly extend. For example, a first height H1 of a first portion of the supporter pattern 8, positioned at a level higher than that of the lower portion 6s_2a of the second isolation layer 6s_2, may be less than a second height H2 of a second portion of the supporter pattern 8 buried in the lower portion 6s_2a of the second isolation layer 6s_2. For example, the first portion of the supporter pattern 8 may extend beyond an upper surface of the lower portion 6s_2a of the second isolation layer 6s_2 and may have the first height H1. The second portion of the supporter pattern 8 may be buried in the lower portion 6s_2a of the second isolation layer 6s_2 and have the second height H2 greater than the first height H1. The second isolation layer 6s_2 may be conformally formed along an inner wall of a second trench T2. For example, the second isolation layer 6s_2 may have a constant thickness. In an example embodiment, a lower surface of the supporter pattern 8 may be positioned at a level lower than that of a lower surface of a lower portion 6s_la of a first isolation layer 6s_1.

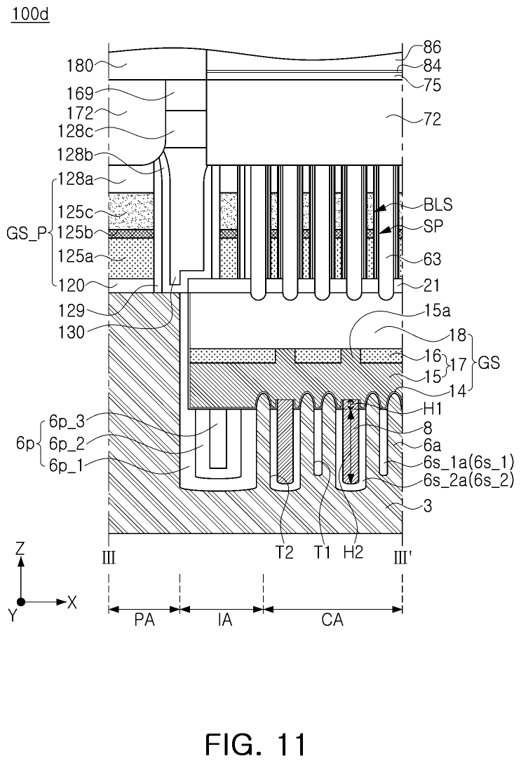

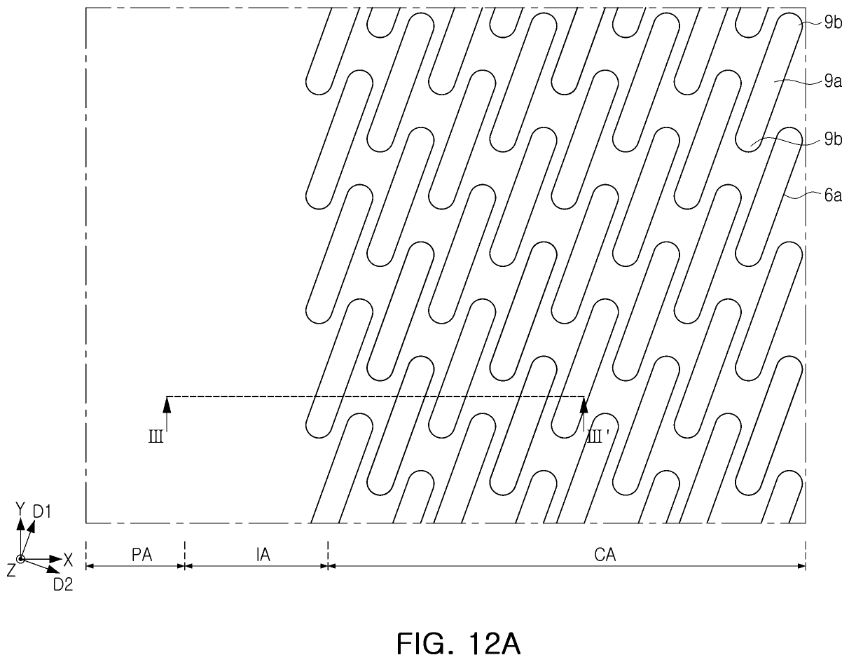

Referring to FIG. 11, a semiconductor device 100d may include a supporter pattern 8 disposed on a lower portion 6s_2a of a second isolation layer 6s_2. In an example embodiment, a first height H1 of a first portion of the supporter pattern 8, positioned at a level higher than that of the lower portion 6s_2a of the second isolation layer 6s_2, may be less than a second height H2 of a second portion of the supporter pattern 8 buried in the lower portion 6s_2a of the second isolation layer 6s_2. For example, the first portion of the supporter pattern 8 may extend beyond an upper surface of the lower portion 6s_2a of the second isolation layer 6s_2, and may have the first height H1. The second portion of the supporter pattern 8 may be buried in the lower portion 6s_2a of the second isolation layer 6s_2 and have the second height H2 greater than the first height H1. In addition, in an example embodiment, a first electrode layer 15 of a cell gate structure GS may include a protrusion portion 15a in contact with a side surface of the second electrode layer 16.

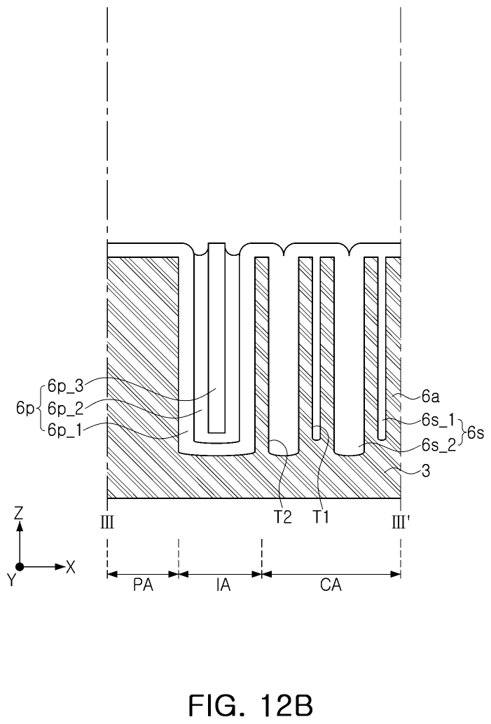

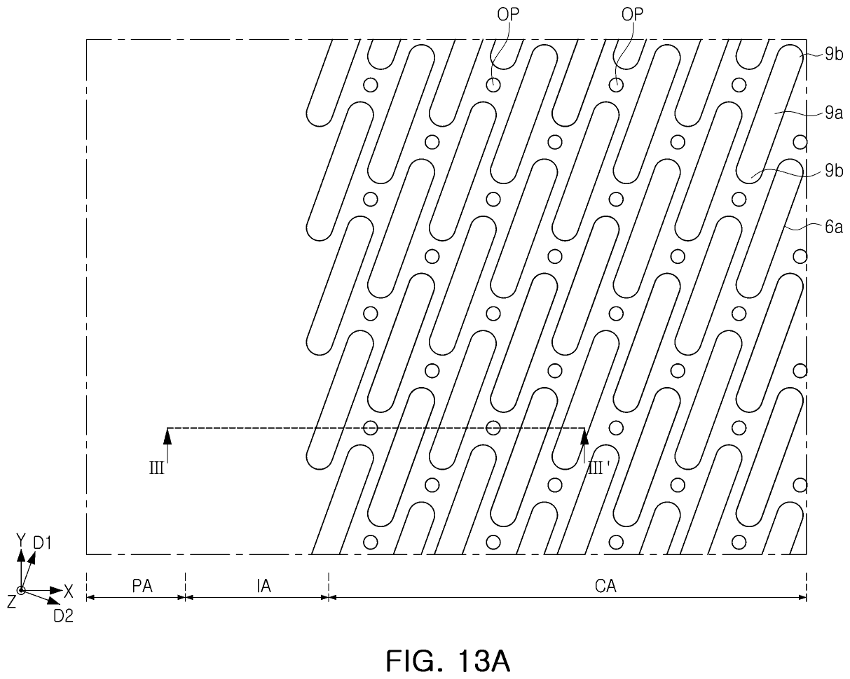

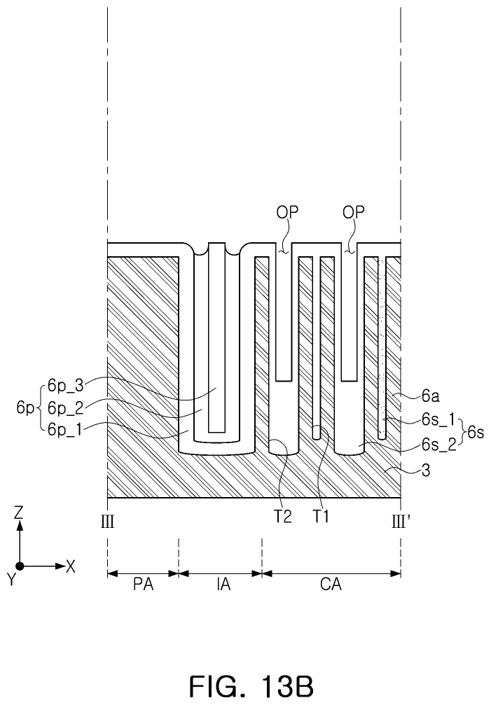

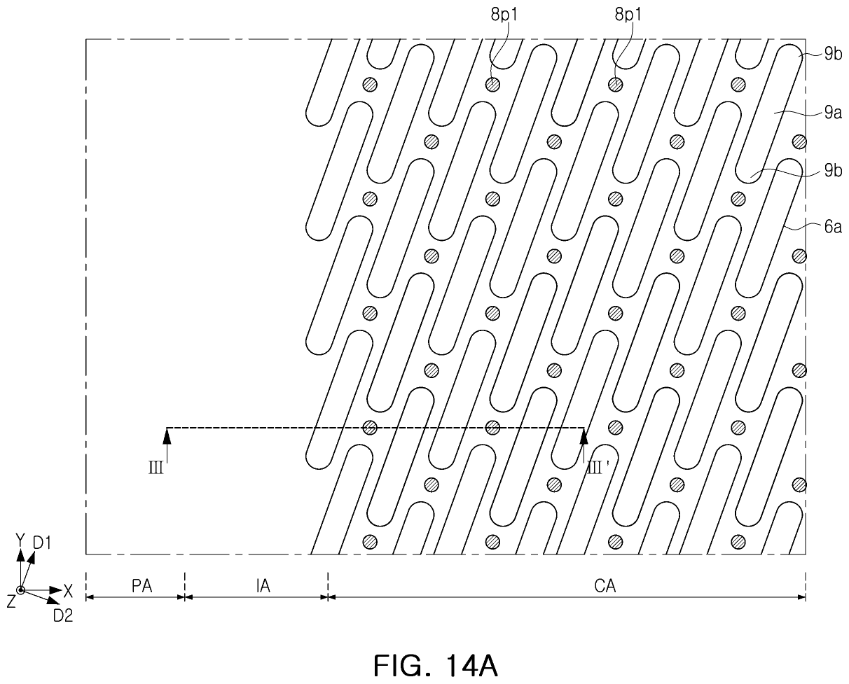

FIGS. 12A, 12B, 13A, 13B, 14A, 14B, 15A, 15B, 16A, 16B, 17A, 17B, 18-20, 21A and 21B are plan views and vertical cross-sectional views of sequential processes of a method of manufacturing a semiconductor device according to an example embodiment. Specifically, FIGS. 12A, 13A, 14A, 15A, 17A, and 21A are plan views of sequential processes of a method of manufacturing a semiconductor device. FIGS. 12B, 13B, 14B, 15B, 17B, 18-20 and 21B are vertical cross-sectional views taken along line III-III′ of FIGS. 12A, 13A, 14A, 15A, 17A, and 21A, respectively.

Referring to FIGS. 12A and 12B, a first isolation layer 6s_1 and a second isolation layer 6s_2 may be formed at a cell region CA of a substrate 3. The second isolation layer 6s_2 may be formed to be deeper than the first isolation layer 6s_1. For example, a lower surface of the first isolation layer 6s_1 may be positioned at the same as or higher than a lower surface of the second isolation layer 6s_2. The first isolation layer 6s_1 and the second isolation layer 6s_2 may be formed by forming a first trench T1 and a second trench T2 at an upper surface of the substrate 3 and depositing an insulating material filling the first trench T1 and the second trench T2. The first isolation layer 6s_1 and the second isolation layer 6s_2 may form a device isolation layer 6s.

A region isolation layer 6p may be formed at an interface region CA. The region isolation layer 6p may be formed to be the same as or deeper than the second isolation layer 6s_2. For example, a lower surface of the second isolation layer 6s_2 may be positioned at the same as or higher than a lower surface of the region isolation layer 6p. The region isolation layer 6p may be formed by forming a trench at the upper surface of the substrate 3 and sequentially depositing a first insulating layer 6p_1, a second insulating layer 6p_2, and a third insulating layer 6p_3 in the trench. The region isolation layer 6p may be formed simultaneously with the device isolation layer 6s, or may be formed using a separate process from the forming of the device isolation layer 6s. An insulating material, included in the device isolation layer 6s and the region isolation layer 6p, may cover the upper surface of the substrate 3.

Referring to FIGS. 13A and 13B, openings OP may be formed by anisotropically etching the second isolation layer 6s_2. The openings OP may be disposed to be spaced apart from each other in an X-direction, a Y-direction, and a first horizontal direction D1. For example, the openings OP may be disposed to be adjacent to ends of each active region 6a in the first horizontal direction D1. Lower surfaces of the openings OP may be positioned between an upper surface and a lower surface of the second isolation layer 6s_2.

In an example embodiment, a process of conformally depositing an insulating layer may be further performed after the openings OP are formed. The insulating layer may include or may be formed of a material which is the same as that of the device isolation layer 6s, for example, silicon oxide. When the active region 6a is exposed in a process of forming the openings OP, the insulating layer may cover the active region 6a.

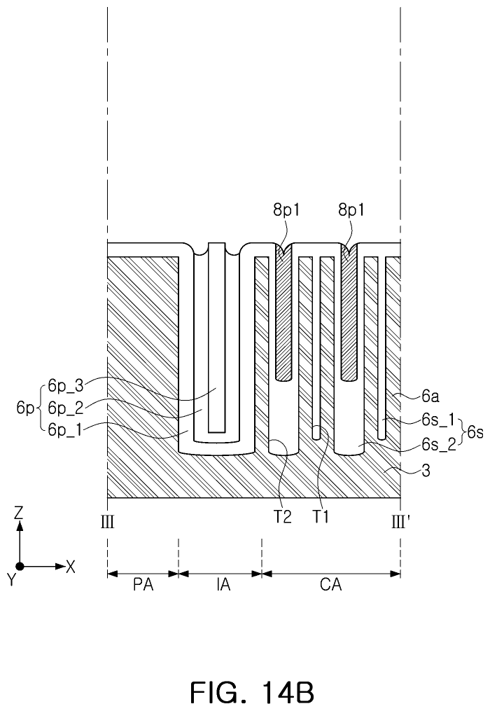

Referring to FIGS. 14A and 14B, first preliminary supporter layers 8p1 may be formed in the openings OP. The first preliminary supporter layers 8p1 may be formed on the second isolation layers 6s_2, and may entirely fill the second trench T2. The first preliminary supporter layers 8p1 may include a material having etch selectivity with respect to the device isolation layer 6s.

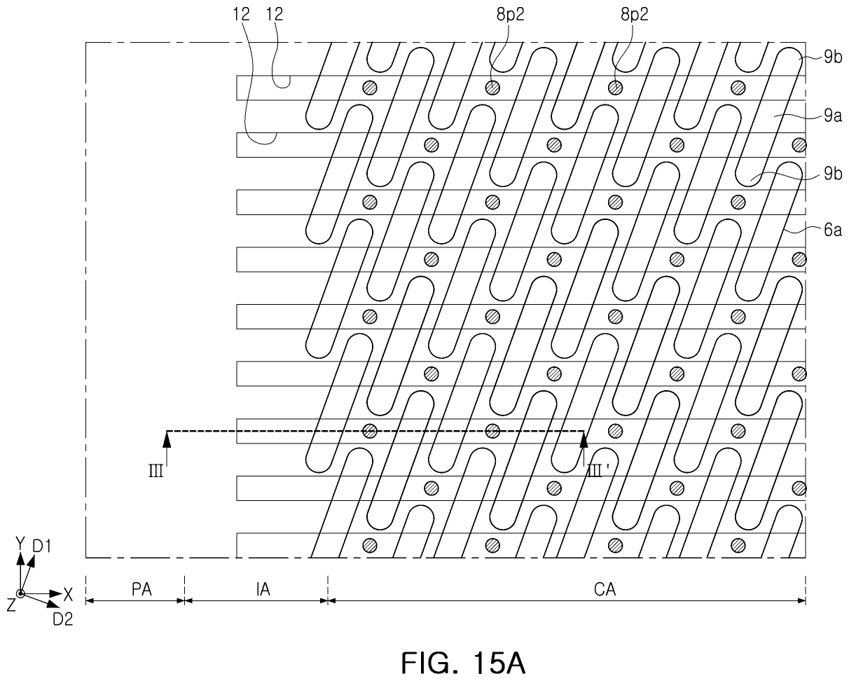

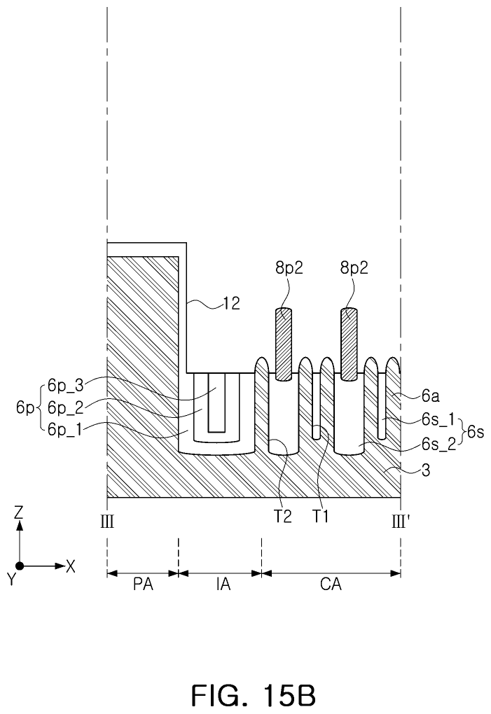

Referring to FIGS. 15A and 15B, gate trenches 12 may be formed using an anisotropic etching process. The gate trenches 12 may extend in the X-direction, and may be spaced apart from each other in the Y-direction. The active region 6a and the device isolation layer 6s may be etched using the etching process. In the cross-sectional view of FIG. 15B, a lower portion 6s_la of the first isolation layer 6s_1 and a lower portion 6s_2a of the second isolation layer 6s_2 may be illustrated after the etching process.

The first preliminary supporter layer 8p1 may also be partially etched in the etching process to form a second preliminary supporter layer 8p2. However, the first preliminary supporter layer 8p1 may include a material having etch selectivity with respect to the device isolation layer 6s, such that an upper end of the second preliminary supporter layer 8p2 may be positioned at a level higher than those of an upper surface of the lower portion 6s_la of the first isolation layer 6s_1 and an upper surface of the lower portion 6s_2a of the second isolation layer 6s_2.

In an example embodiment, the gate trenches 12 may extend to the interface region IA. For example, the region isolation layer 6p may be etched using the etching process.

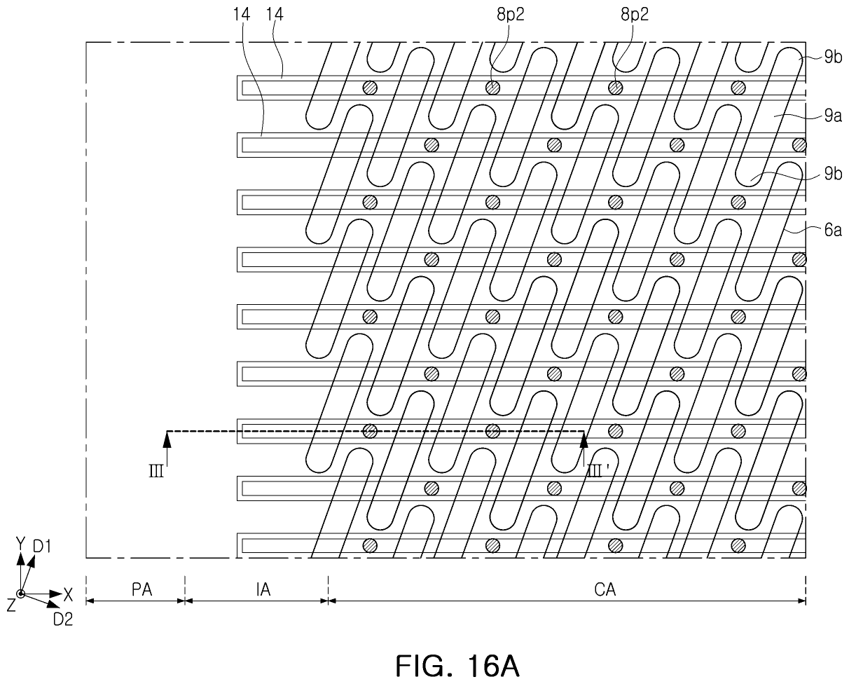

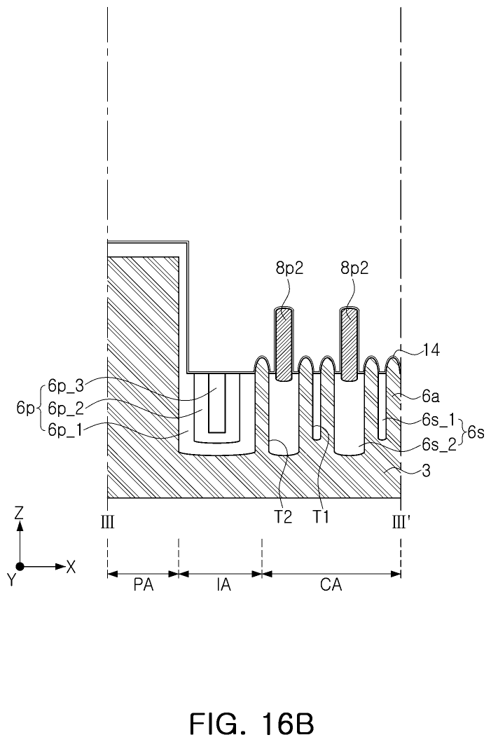

Referring to FIGS. 16A and 16B, a gate dielectric layer 14 may be formed on the gate trench 12. The gate dielectric layer 14 may be conformally formed along an inner wall of the gate trench 12, and may cover the active region 6a, the device isolation layer 6s, the region isolation layer 6p, and the second preliminary supporter layer 8p2.

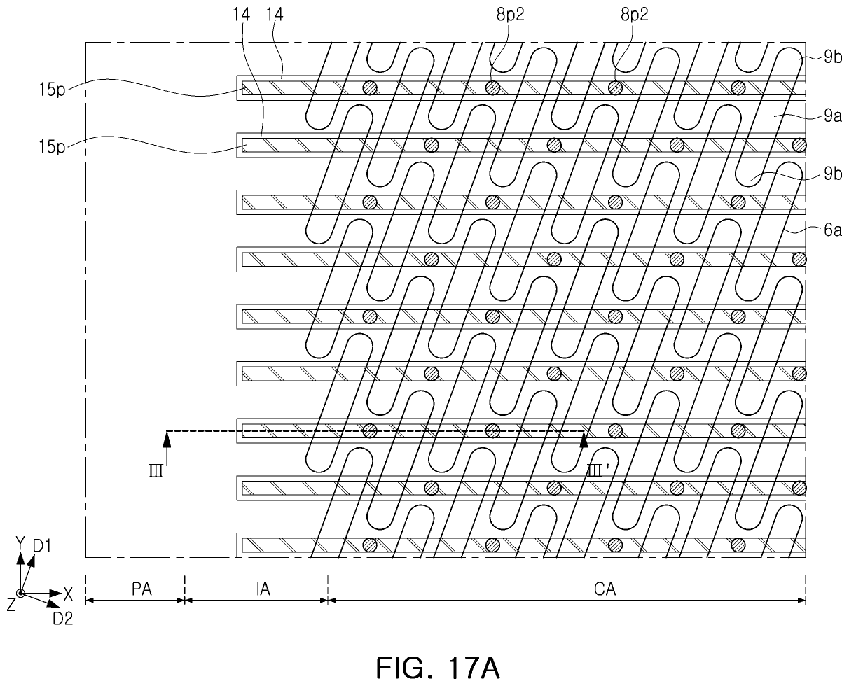

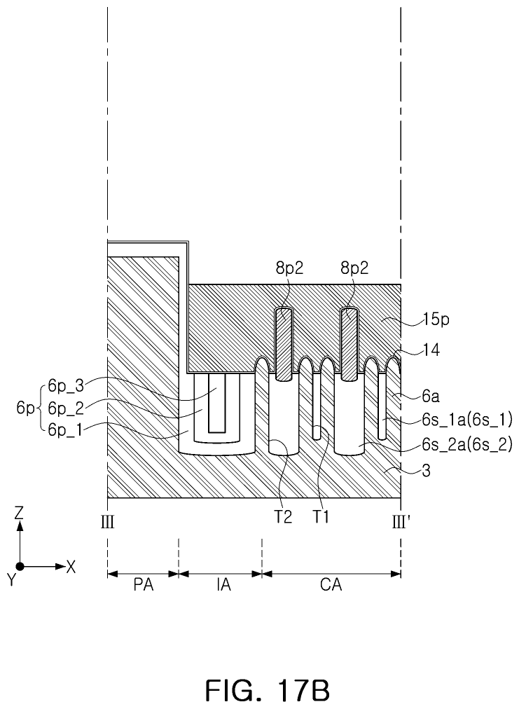

Referring to FIGS. 17A and 17B, a first electrode material layer 15p may be formed on the gate dielectric layer 14. The first electrode material layer 15p may extend in the X-direction and may be disposed in the gate trench 12. An upper surface of the first electrode material layer 15p may be formed to be higher than an upper end of the second preliminary supporter layer 8p2, such that the second preliminary supporter layer 8p2 may not be exposed.

Referring to FIG. 18, an etch-back process may be performed to partially etch the first electrode material layer 15p. An upper surface of the etched first electrode material layer 15p may be positioned at a level lower than that of the upper end of the second preliminary supporter layer 8p2. In an example embodiment, the gate dielectric layer 14, covering the second preliminary supporter layer 8p2, may be partially etched to expose the second preliminary supporter layer 8p2 after the etch-back process.

Referring to FIG. 19, the second preliminary supporter layer 8p2 may be etched using an etching process to form a supporter pattern 8. An upper surface of the supporter pattern 8 may be positioned at a level lower than that of the upper surface of the etched first electrode material layer 15p. The etching process may be a wet etching process or a dry etching process. After the supporter pattern 8 is formed, a process of etching a portion of the gate dielectric layer 14, covering a side surface of the first electrode material layer 15p, may be further performed.

Referring to FIG. 20, a first electrode layer 15 may be formed by depositing a conductive material on the first electrode material layer 15p to cover the supporter pattern 8 and performing an etch-back process. The conductive material may include a material which is the same as that of the first electrode material layer 15p. The first electrode layer 15 may be in contact with an upper surface of the supporter pattern 8.

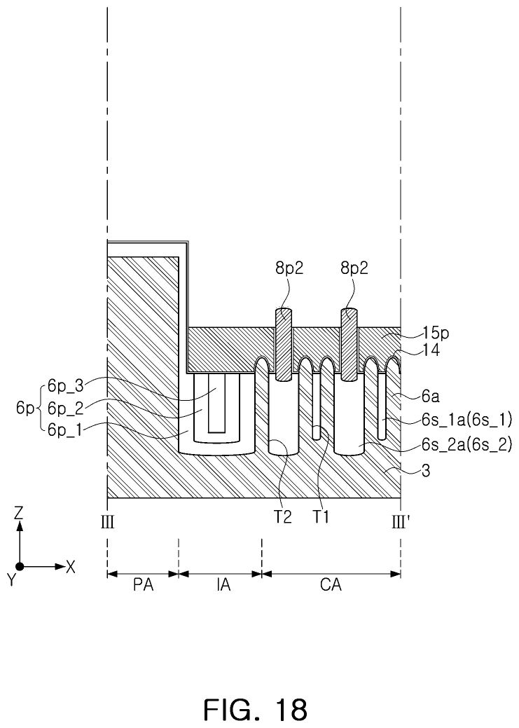

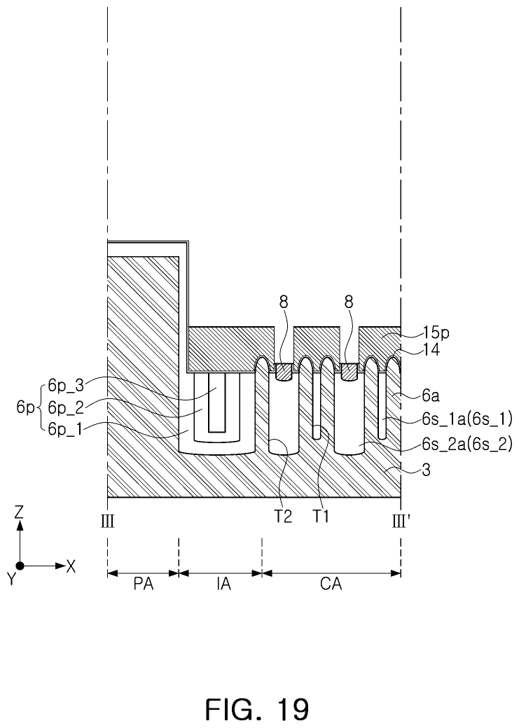

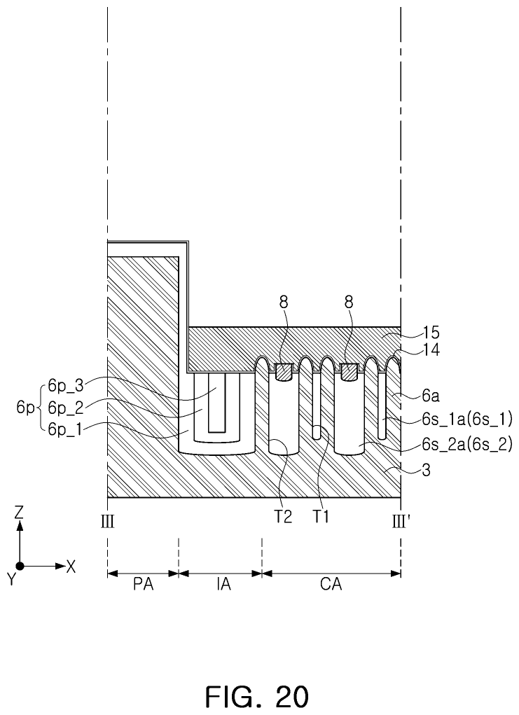

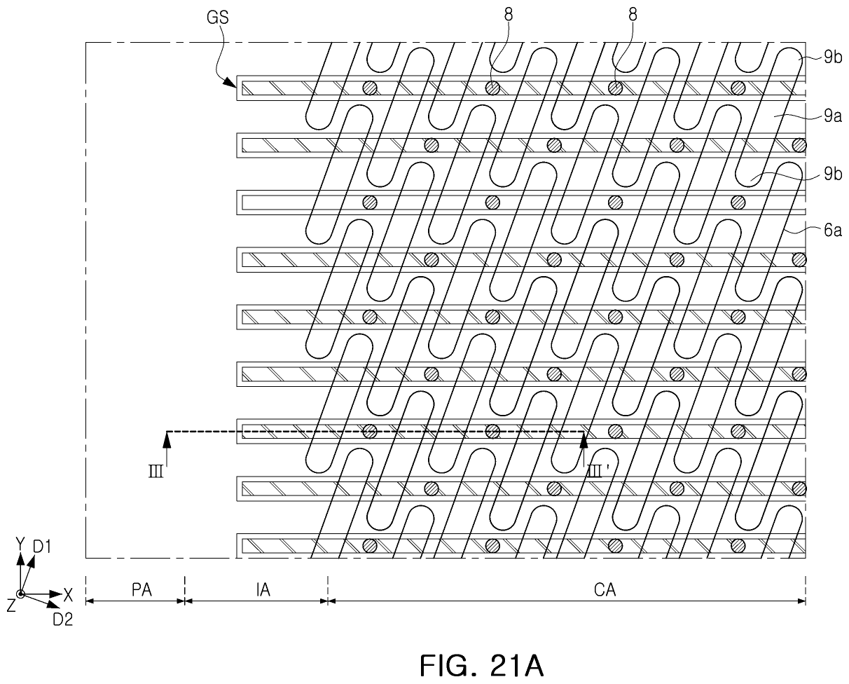

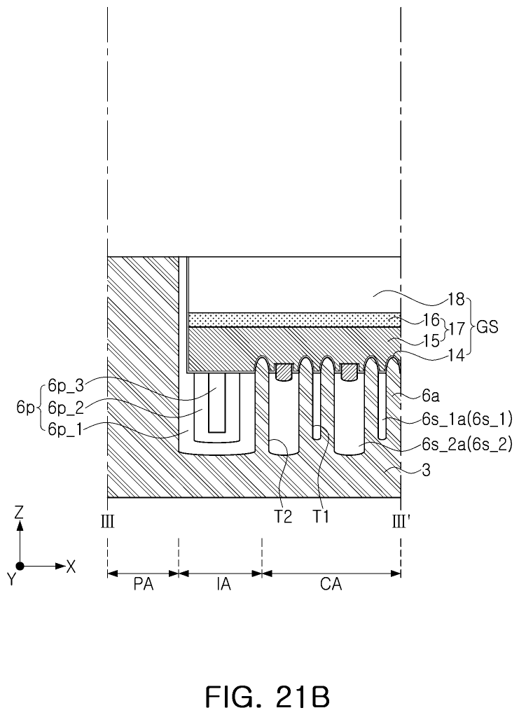

Referring to FIGS. 21A and 21B, a second electrode layer 16 and a gate capping layer 18 may be formed on the first electrode layer 15. The first electrode layer 15 and the second electrode layer 16 may form a gate electrode 17, and the gate dielectric layer 14, the gate electrode 17, and the gate capping layer 18 may form a cell gate structure GS. An upper surface of the cell gate structure GS may be coplanar with the upper surface of the substrate 3. When viewed in a plan view, the cell gate structures GS may extend in the X-direction, and may be spaced apart from each other in the Y-direction. Each supporter pattern 8 may vertically overlap a corresponding cell gate structure GS.

In a process of forming the gate trench 12, a region in which the gate trenches 12 are not formed may protrude from the upper surface of the substrate 3 to have a fin shape, and extend in the X-direction. A region in which the gate trenches 12 are not formed may collapse due to stress when the gate electrode 17 is formed. However, according to example embodiments of the present inventive concept, the supporter pattern 8 may be formed on the second isolation layer 6s_2, thereby preventing the region in which the gate trenches 12 are not formed from collapsing.

Referring back to FIGS. 2 to 5, on the cell region CA, a buffer layer 21, a bit line structure BLS, a spacer structure SP, a contact plug 60, a fence structure 63, a metal-semiconductor compound layer 66, a landing pad 69, an insulating pattern 72, and a capacitor structure 80 may be formed on the substrate 3.

In the peripheral circuit region PA and the interface region IA, a peripheral gate structure GS_P, a peripheral gate spacer 129, a first peripheral capping layer 128b, a second peripheral capping layer 128c, a lower interlayer insulating layer 130, a peripheral interconnection 169, a peripheral insulating pattern 172, and an upper interlayer insulating layer 180 may be formed to manufacture the semiconductor device 100.

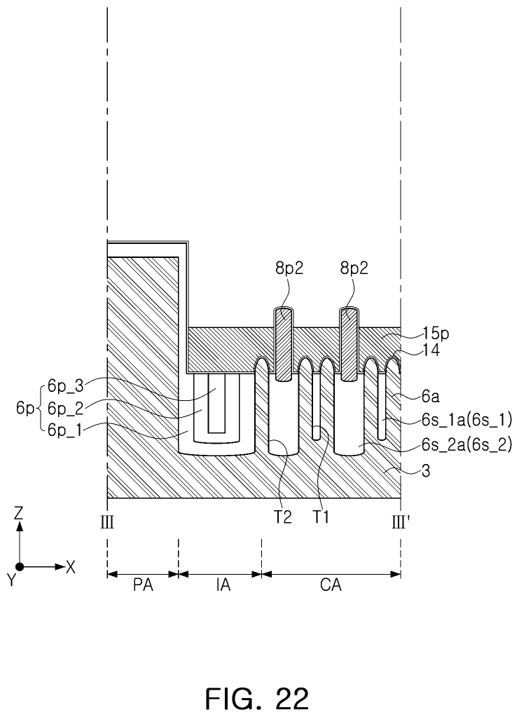

FIGS. 22 to 25 are vertical cross-sectional views of sequential processes of a method of manufacturing a semiconductor device according to an example embodiment. Specifically, FIGS. 22 to 25 are cross-sectional views of sequential processes of a method of manufacturing a semiconductor device, and may correspond to FIG. 9.

Referring to FIG. 22, after the process described with reference to FIG. 16B, a first electrode material layer 15p may be formed by depositing a conductive material. An upper surface of the first electrode material layer 15p may be formed lower than an upper end of a second preliminary supporter layer 8p2. The second preliminary supporter layer 8p2 and a gate dielectric layer 14, covering the second preliminary supporter layer 8p2, may upwardly protrude from the upper surface of the first electrode material layer 15p.

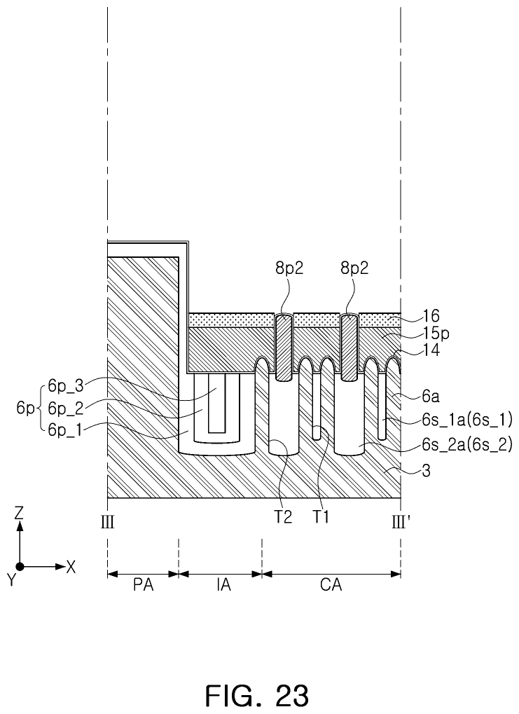

Referring to FIG. 23, a second electrode layer 16 may be formed on the first electrode material layer 15p. The second electrode layer 16 may be formed by forming a conductive material to cover the first electrode material layer 15p and etching back the conductive material to expose the second preliminary supporter layer 8p2.

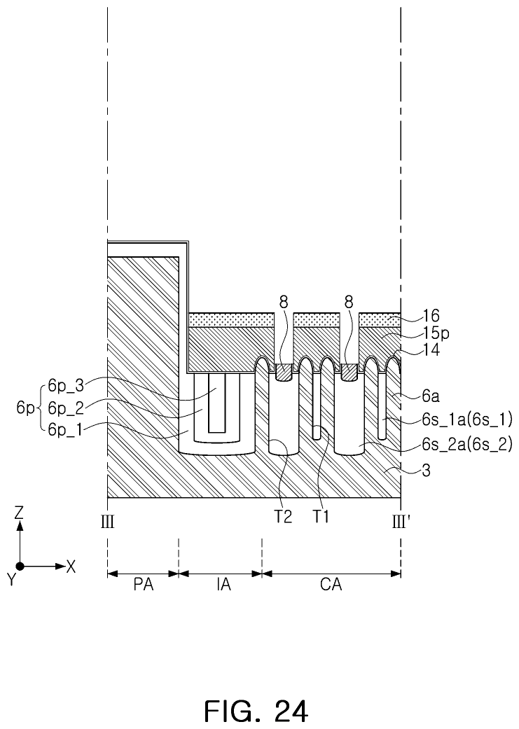

Referring to FIG. 24, the second preliminary supporter layer 8p2 may be etched to form a supporter pattern 8, and side surfaces of the first electrode material layer 15p and the second electrode layer 16 may be exposed. An upper surface of the supporter pattern 8 may be positioned at a level lower than that of the upper surface of the first electrode material layer 15p. After the supporter pattern 8 is formed, a portion of the gate dielectric layer 14, covering the side surfaces of the first electrode material layer 15p and the second electrode layer 16, may be etched.

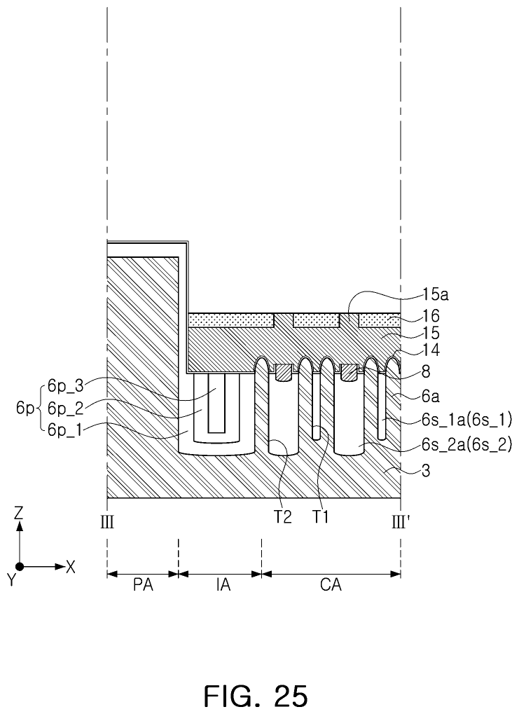

Referring to FIG. 25, the first electrode layer 15 may be formed by forming a conductive material on the first electrode material layer 15p and etching back the conductive material to expose an upper surface of the second electrode layer 16. A protrusion portion 15a of the first electrode layer 15 may be in contact with the side surface of the second electrode layer 16, and an upper surface of the protrusion portion 15a may be coplanar with the upper surface of the second electrode layer 16.

Referring to FIG. 9, the cell gate structure GS may be formed by forming a gate capping layer 18 on the second electrode layer 16. The semiconductor device 100b may be manufactured using a subsequent semiconductor device manufacturing process.

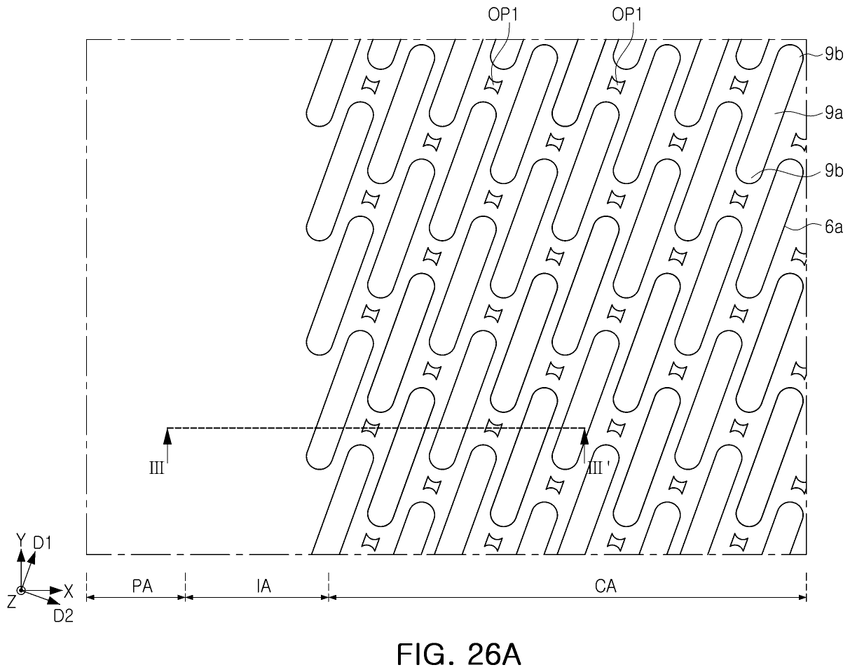

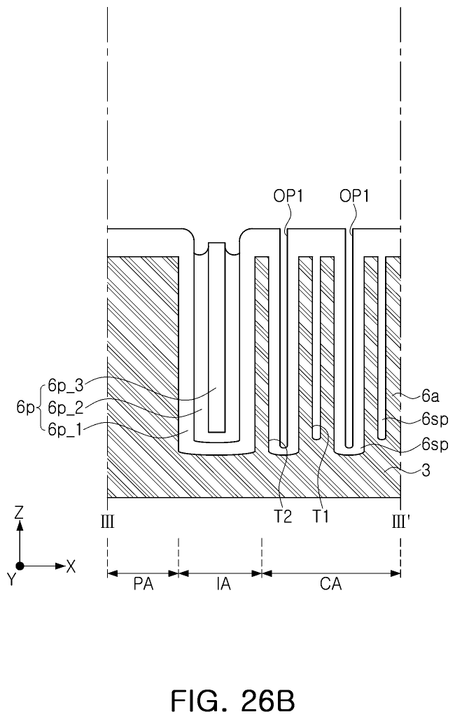

FIGS. 26A, 26B, 27A, 27B, 28A, and 28B are plan views and vertical cross-sectional views of sequential processes of a method of manufacturing a semiconductor device according to an example embodiment. Specifically, FIGS. 26A, 27A, and 28A are plan views of sequential processes of a method of manufacturing a semiconductor device. FIGS. 26B, 27B, and 28B are cross-sectional views taken along line III-III′ illustrated in FIGS. 26A, 27A, and 28A, respectively, and may correspond to FIG. 10.

Referring to FIGS. 26A and 26B, a first trench T1 and a second trench T2 are formed on a substrate 3, and an isolation material layer 6sp may be formed in the first trench T1 and the second trench T2. The isolation material layer 6sp may be conformally disposed along an inner wall of the second trench T2, and may define a first opening OP1. For example, the isolation material layer 6sp may not entirely fill the second trench T2. For example, the first openings OP1 may be disposed adjacent to ends of each active region 6a in a first horizontal direction D1. When viewed in a plan view, the first opening OP1 may have concave side surfaces in the first horizontal direction D1. The isolation material layer 6sp may entirely fill the first trench T1.

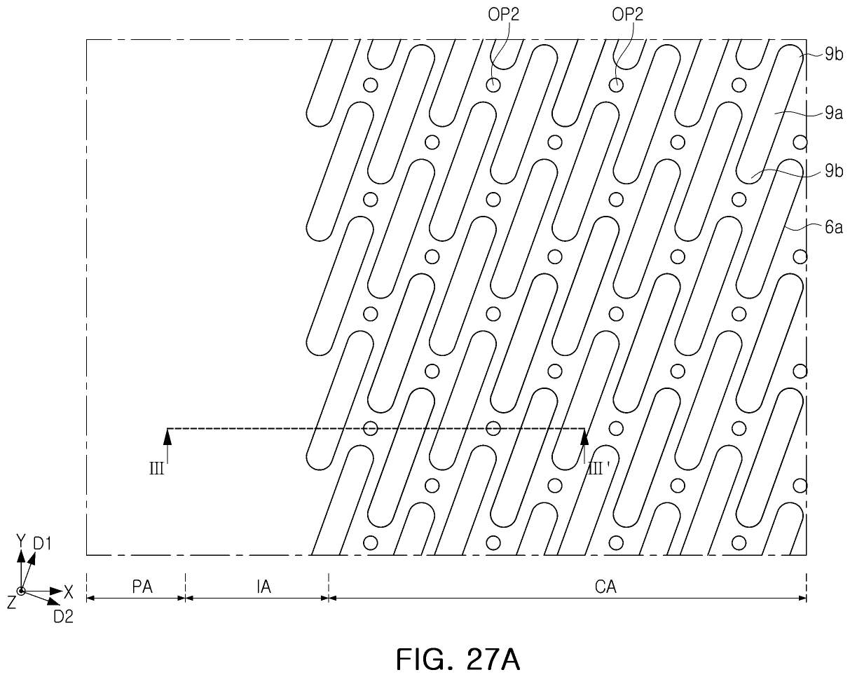

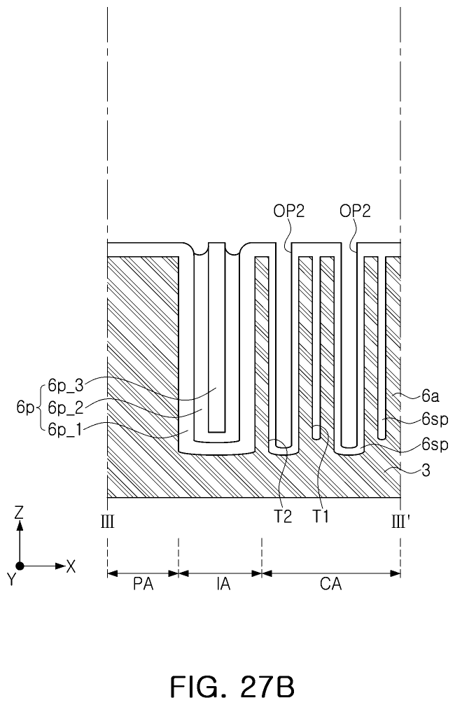

Referring to FIGS. 27A and 27B, a wet etching process may be performed, and the isolation material layer 6sp may be partially etched. The first opening OP1 may be expanded using the etching process to form a second opening OP2. When viewed in a plan view, the second opening OP2 may have a circular or oval shape. In some example embodiments, in order to prevent the active region 6a from being exposed by the etching process, a process of conformally depositing a material which is the same as that of the isolation material layer 6sp may be further performed.

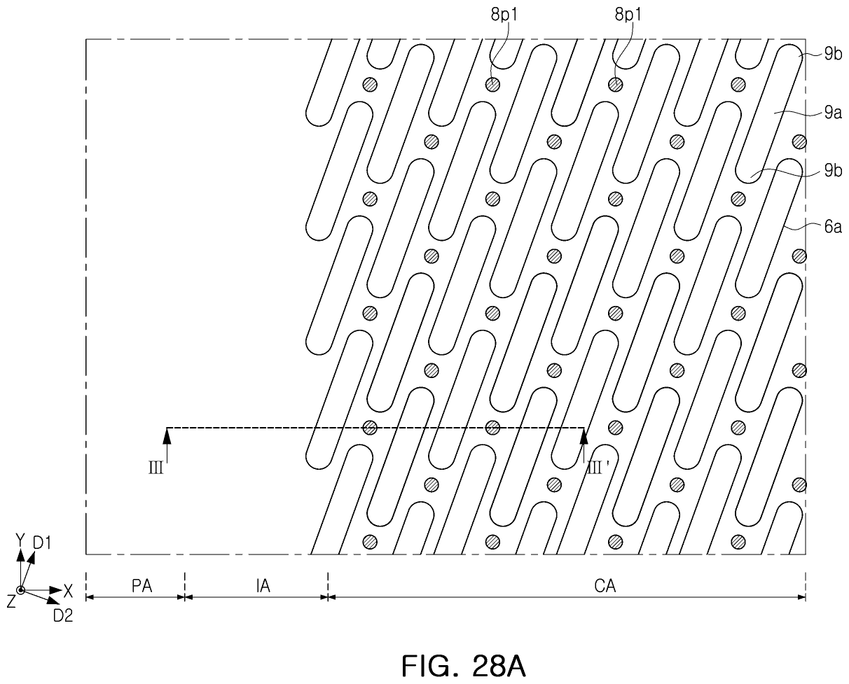

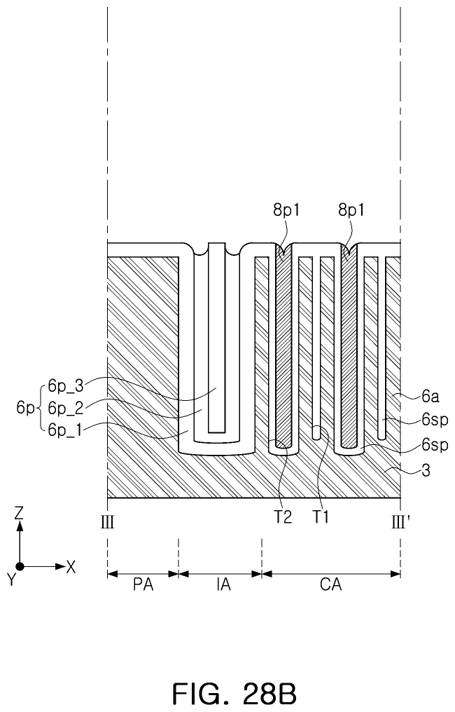

Referring to FIGS. 28A and 28B, first preliminary supporter layers 8p1 may be formed in the second openings OP2. The first preliminary supporter layers 8p1 may be formed on the isolation material layer 6sp, and may entirely fill the second trench T2. The first preliminary supporter layers 8p1 may include or may be formed of a material having etch selectivity with respect to the isolation material layer 6sp. In an example embodiment, the first preliminary supporter layers 8p1 may include or may be formed of at least one of carbon (C)-doped polysilicon, silicon germanium (SiGe), and silicon nitride (SiN). In some example embodiments, the first preliminary supporter layers 8p1 may include or may be formed of a conductive material such as metal or metal nitride. For example, the first preliminary supporter layers 8p1 may include or may be formed of at least one of titanium (Ti), titanium nitride (TiN), tantalum (Ta), tantalum nitride (TaN), tungsten (W), tungsten nitride (WN), molybdenum (Mo), and aluminum (Al).

Thereafter, the process described with reference to FIGS. 15A to 21B may be performed, and the cell gate structure GS illustrated in FIG. 10 may be formed. The semiconductor device 100c may be manufactured using a subsequent semiconductor device manufacturing process.

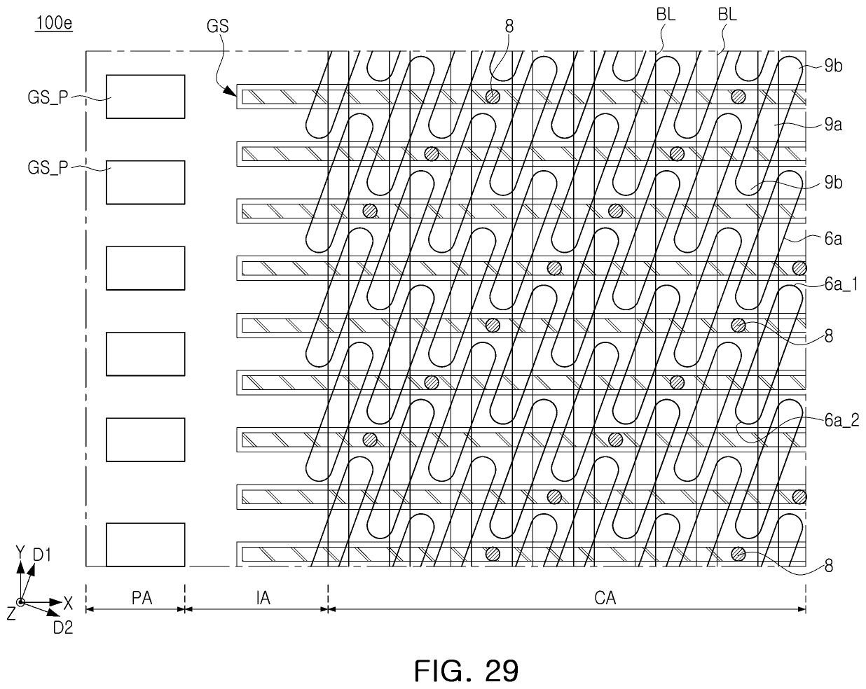

FIGS. 29 to 31 are plan views of semiconductor devices according to example embodiments.

Referring to FIG. 29, a semiconductor device 100e may include supporter patterns 8 disposed between active regions 6a. The arrangement of the supporter patterns 8 illustrated in FIG. 29 may be different from the arrangement of the supporter patterns 8 illustrated in FIG. 2.

In an example embodiment, two active regions 6a, arranged in a first horizontal direction D1, may be disposed between two supporter patterns 8, arranged to be adjacent to each other in the first horizontal direction D1. For example, the active regions 6a may have a first end 6a_1 and a second end 6a_2 spaced apart from each other in the first horizontal direction D1. With respect to each active region 6a, one of the supporter patterns 8 may be disposed to be adjacent to only the first end 6a_1 or the second end 6a_2. For example, in FIG. 2, a supporter pattern 8 may be positioned in each second trench T2, surrounded by four active regions, in both the X-direction and the Y-direction while, in FIG. 29, the supporter patterns 8 may be arranged in the second trenches T2, skipping one trench in both the X-direction and the Y-direction.

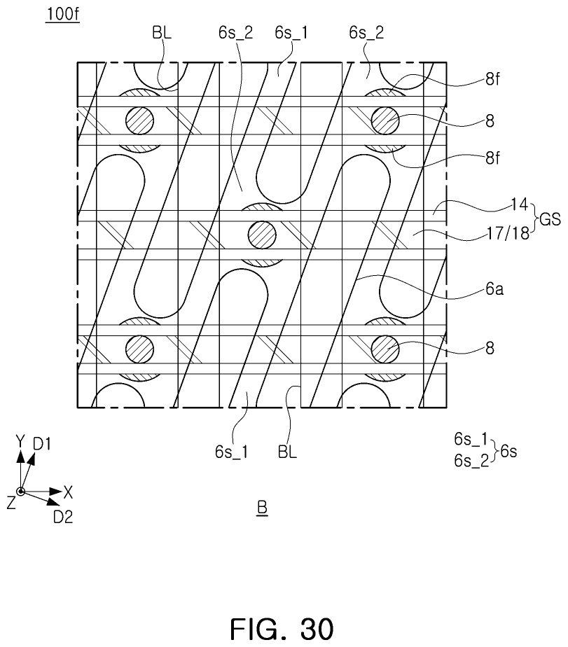

Referring to FIG. 30, a semiconductor device 100f may include a supporter pattern 8 vertically overlapping a cell gate structure GS. In an example embodiment, the semiconductor device 100f may further include a supporter material layer 8f which is spaced apart from the supporter pattern 8 in a Y-direction and which is in contact with a side surface of the cell gate structure GS. For example, a pair of supporter material layers 8f may be spaced apart from each other in the Y-direction with the cell gate structure GS interposed therebetween. The pair of supporter material layers 8f may be in contact with opposite side surfaces of the cell gate structure GS.

In the process of forming the gate trench 12 described with reference to FIGS. 15A and 15B, when a horizontal width of the first preliminary supporter layer 8p1 in the Y-direction is greater than a horizontal width of the gate trench 12 in the Y-direction, a portion of the first preliminary supporter layer 8p1 may remain without being etched. In an example embodiment, the portion of the first preliminary supporter layer 8p1, being not etched in the process of forming of the gate trench 12, may be replaced with a conductive material which is the same as that of the first electrode layer 15 using the process described with reference to FIGS. 19 and 20.

In an example embodiment, the supporter material layer 8f may include or may be formed of at least one of carbon (C)-doped polysilicon, silicon germanium (SiGe), and silicon nitride (SiN). In some example embodiments, the supporter material layer 8f may include or may be formed of a conductive material such as metal or metal nitride. For example, the supporter material layer 8f may include or may be formed of at least one of titanium (Ti), titanium nitride (TiN), tantalum (Ta), tantalum nitride (TaN), tungsten (W), tungsten nitride (WN), molybdenum (Mo), and aluminum (Al).

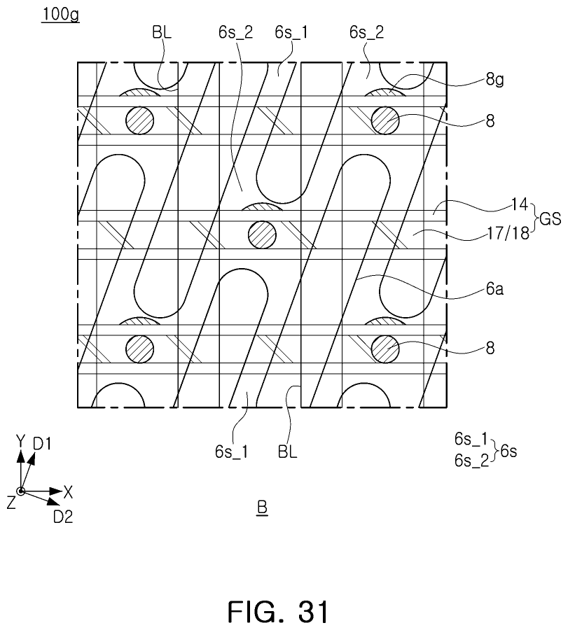

Referring to FIG. 31, a semiconductor device 100g may include a supporter pattern 8 vertically overlapping the cell gate structure GS. In an example embodiment, the semiconductor device 100g may further include a supporter material layer 8g spaced apart from the supporter pattern 8 in the Y-direction, and the supporter material layer 8g may be in contact with a side surface of the cell gate structure GS. For example, the supporter material layers 8g may be disposed on one side surface, among side surfaces of the cell gate structure GS. For example, the cell gate structure GS may have a first side surface and a second side surface, perpendicular to the Y-direction, and the supporter material layers 8g may be disposed only on the first side surface or on the second side surface.

When the first preliminary supporter layer 8p1 is misaligned with the gate trench 12 in the process of forming the gate trench 12 described with reference to FIGS. 15A and 15B, a portion of the first preliminary supporter layer 8p1 may remain without being etched. The supporter material layers 8g may include a material which is the same as that of the supporter material layers 8f described with reference to FIG. 30.

According to example embodiments of the present inventive concept, a supporter pattern may be formed on a device isolation layer before a gate trench is formed, thereby preventing a region in which gate trenches are not formed from collapsing.

While example embodiments have been shown and described above, it will be apparent to those skilled in the art that modifications and variations could be made without departing from the scope of the present inventive concept as defined by the appended claims.

What is claimed is:

1. A semiconductor device comprising:
a plurality of active regions disposed at a substrate;
a device isolation layer disposed at the substrate and surrounding each of the plurality of active regions;
a supporter pattern surrounded by the device isolation layer and disposed in a space between two active regions of the plurality of active regions;
a cell gate structure intersecting the plurality of active regions, the cell gate structure including a gate dielectric layer, a gate electrode on the gate dielectric layer, and a gate capping layer on the gate electrode; and
a bit line structure intersecting one of the plurality of active regions and the cell gate structure,
wherein a lower surface of the supporter pattern is in contact with the device isolation layer, and an upper surface of the supporter pattern is in contact with the gate electrode.

2. The semiconductor device of claim 1,
wherein at least a portion of a side surface of the supporter pattern is covered by the gate dielectric layer, and
wherein the side surface of the supporter pattern connects the upper surface of the supporter pattern to the lower surface of the supporter pattern.

3. The semiconductor device of claim 1,
wherein a plurality of upper ends of portions of the plurality of active regions, overlapping the cell gate structure in a vertical direction, are disposed at a first vertical level,
wherein the upper surface of the supporter pattern is disposed at a second vertical level, and
wherein the second vertical level is the same as or lower than the first vertical level.

4. The semiconductor device of claim 1,
wherein the device isolation layer includes a first isolation layer and a second isolation layer,
wherein a lower surface of the first isolation layer is higher than a lower surface of the second isolation layer,
wherein the second isolation layer includes a lower portion below the cell gate structure, and an upper portion on the lower portion, and
wherein the supporter pattern is disposed in a space between the lower portion of the second isolation layer and the gate electrode.

5. The semiconductor device of claim 4,
wherein the lower surface of the supporter pattern and a side surface of the supporter pattern are in contact with the lower portion of the second isolation layer.

6. The semiconductor device of claim 4,
wherein the upper surface of the supporter pattern is positioned at a level higher than an upper surface of the lower portion of the second isolation layer.

7. The semiconductor device of claim 4,
wherein the lower surface of the supporter pattern is positioned at a level lower than an upper surface of the lower portion of the second isolation layer.

8. The semiconductor device of claim 4,
wherein a first height of a first portion of the supporter pattern, extending beyond an upper surface of the lower portion of the second isolation layer, is less than a second height of a second portion of the supporter pattern buried in the lower portion of the second isolation layer.

9. The semiconductor device of claim 1,
wherein the supporter pattern includes a metal layer and a barrier layer covering a side surface and a lower surface of the metal layer, and
wherein the barrier layer is in contact with the device isolation layer and the gate dielectric layer.

10. The semiconductor device of claim 1,
wherein the gate electrode includes a first electrode layer, and a second electrode layer on the first electrode layer, and
wherein the upper surface of the supporter pattern is in contact with the first electrode layer.

11. The semiconductor device of claim 10,
wherein a thickness of a first portion of the first electrode layer, overlapping the device isolation layer in a vertical direction, is a first thickness,
wherein a minimum thickness of a second portion of the first electrode layer, overlapping one of the plurality of active regions in the vertical direction, is a second thickness,
wherein a third portion of the first electrode layer, overlapping the supporter pattern in the vertical direction, has a third thickness, and
wherein the third thickness is greater than the second thickness and less than the first thickness.

12. The semiconductor device of claim 10,
wherein the first electrode layer includes a protrusion portion protruding in a vertical direction from an upper surface of the first electrode layer, the protrusion portion overlapping the supporter pattern in the vertical direction.

13. The semiconductor device of claim 12,
wherein the protrusion portion is in contact with a side surface of the second electrode layer, and
wherein an upper surface of the protrusion portion is coplanar with an upper surface of the second electrode layer.

14. The semiconductor device of claim 1,
wherein the supporter pattern includes at least one of carbon-doped polysilicon, silicon germanium, and silicon nitride.

15. A semiconductor device comprising:
a substrate having a first trench and a second trench extending from an upper surface of the substrate toward a lower surface of the substrate, wherein a lower surface of the first trench is higher than a lower surface of the second trench;
a first active region disposed at the substrate and defined by the first trench and the second trench, wherein the first active region extends in a first horizontal direction;
a device isolation layer including a first isolation layer filling the first trench, and a second isolation layer filling the second trench;
a supporter pattern disposed on the second isolation layer;
a cell gate structure intersecting the first active region, the cell gate structure extending in a second horizontal direction intersecting the first horizontal direction, and the cell gate structure including a gate dielectric layer, a gate electrode on the gate dielectric layer, and a gate capping layer on the gate electrode; and
a bit line structure intersecting the first active region and the cell gate structure, the bit line structure extending in a third horizontal direction intersecting the first horizontal direction and the second horizontal direction,
wherein a lower surface of the supporter pattern is in contact with the device isolation layer, and an upper surface of the supporter pattern is in contact with the gate electrode.

16. The semiconductor device of claim 15, further comprising:
a second active region disposed at the substrate,
wherein the second isolation layer is disposed in a space between the first active region and the second active region which are spaced apart from each other in the first horizontal direction.

17. The semiconductor device of claim 15, further comprising:
a pair of supporter material layers spaced apart from each other in the third horizontal direction,
wherein the supporter pattern is disposed in a space between pair of supporter material layers, and
wherein the pair of supporter material layers are in contact with opposite side surfaces of the cell gate structure.

18. The semiconductor device of claim 15, further comprising:
a plurality of supporter material layers spaced apart from each other in the first horizontal direction,
wherein the cell gate structure has a first side surface and a second side surface, perpendicular to the third horizontal direction, and
wherein the supporter material layers are disposed only on the first side surface of the cell gate structure.

19. The semiconductor device of claim 15,
wherein a horizontal width of the supporter pattern in the second horizontal direction is less than a horizontal width of the second isolation layer in the second horizontal direction.

20. A semiconductor device comprising:
a plurality of active regions disposed at a substrate;
a device isolation layer disposed at the substrate and surrounding each of the plurality of active regions;
a supporter pattern surrounded by the device isolation layer and disposed in a space between two active regions of the plurality of active regions;
a plurality of cell gate structures intersecting the plurality of active regions, each of the plurality of cell gate structures including a gate dielectric layer, a gate electrode on the gate dielectric layer, and a gate capping layer on the gate electrode;
a plurality of bit line structures intersecting the plurality of active regions and the plurality of cell gate structures;
a contact plug disposed on a side surface of one of the plurality of bit line structures, wherein the contact plug is electrically connected to one of the plurality of active regions;
a landing pad on the contact plug; and
a capacitor structure on the landing pad,
wherein a lower surface of the supporter pattern is in contact with the device isolation layer, an upper surface of the supporter pattern is in contact with the gate electrode, and a side surface of the supporter pattern is in contact with the device isolation layer and the gate dielectric layer.
